(19) United States
(12) Patent Application Publication
(10) Pub. No.: US 2023/0016278 A1
(43) Pub. Date: Jan. 19, 2023

(54) SEMICONDUCTOR MEMORY DEVICE AND MANUFACTURING METHOD OF SEMICONDUCTOR MEMORY DEVICE

(71) Applicant: SK hynix Inc., Icheon-si Gyeonggi-do (KR)

(72) Inventor: Won Geun CHOI, Icheon-si Gyeonggi-do (KR)

(73) Assignee: SK hynix Inc., Icheon-si Gyeonggi-do (KR)

(21) Appl. No.: 17/844,258

(22) Filed: Jun. 20, 2022

(30) Foreign Application Priority Data
Jul. 13, 2021 (KR) 10-2021-0091846
May 19, 2022 (KR) 10-2022-0061694

(51) Int. Cl. H01L 27/11582; H01L 27/11565

(52) U.S. Cl. CPC H01L 27/11582; H01L 27/11565

(57) ABSTRACT

There are provided a semiconductor memory device and a manufacturing method of a semiconductor memory device. The semiconductor memory device includes: a first channel structure and a second channel structure, extending in a first direction; a third channel structure disposed between the first channel structure and the second channel structure, the third channel structure extending in the first direction; and a plurality of conductive layers surrounding the first channel structure, the second channel structure, and the third channel structure, the plurality of conductive layers being stacked to be spaced apart from each other in the first direction. The third channel structure is spaced apart from the first channel structure and the second channel structure without interposition of the plurality of conductive layers.

### CROSS-REFERENCE TO RELATED APPLICATION

The present application claims priority under 35 U.S.C. § 119(a) to Korean patent application number 10-2021-0091846 filed on Jul. 13, 2021 and Korean patent application number 10-2022-0061694 filed on May 19, 2022, in the Korean Intellectual Property Office, the entire disclosure of which is incorporated by reference herein.

### BACKGROUND

### 1. Technical Field

Various embodiments of the present disclosure generally relates to a semiconductor memory device and a manufacturing method of a semiconductor memory device, and more particularly, to a three-dimensional semiconductor memory device and a manufacturing method of a three-dimensional semiconductor memory device.

### 2. Related Art

A semiconductor memory device may include a plurality of memory cells capable of storing data. A plurality of memory cells of a three-dimensional semiconductor memory device may be three-dimensionally arranged. In the three-dimensional semiconductor memory device, the plurality of memory cells may be connected in series by a channel structure penetrating a gate stack structure.

### SUMMARY

In accordance with an embodiment of the present disclosure, there is provided a semiconductor memory device including: a first channel structure extending in a first direction; a second channel structure extending in the first direction; a third channel structure extending in the first direction, wherein the third channel structure is disposed between the first channel structure and the second channel structure; and a plurality of conductive layers surrounding the first channel structure, the second channel structure, and the third channel structure, wherein the plurality of conductive layers are stacked in the first direction and are spaced apart from each other in the first direction, and wherein the third channel structure is spaced apart from the first channel structure without interposition of the plurality of conductive layers between the third channel structure and the first channel structure, and wherein the third channel structure is spaced apart from the second channel structure without interposition of the plurality of conductive layers between the third channel structure and the second channel structure.

In accordance with another embodiment of the present disclosure, there is provided a semiconductor memory device including: a plurality of bit lines; a doped semiconductor structure overlapping with the plurality of bit lines; a gate stack structure including a plurality of conductive layers disposed to be spaced apart from each other in a first direction in which the doped semiconductor structure faces the plurality of bit lines, the gate stack structure including a first channel hole and a second channel hole, wherein the first channel hole and the second channel hole penetrate the plurality of conductive layers, and wherein the first channel hole and the second channel hole intersect each other; a first channel structure disposed inside the first channel hole; a second channel structure disposed inside the first channel hole, wherein the second channel hole isolates the first channel structure from the second channel structure; a first memory layer extending along a sidewall of the first channel hole; a second memory layer extending along a sidewall of the first channel hole, wherein the second channel hole isolates the first memory layer from the second memory layer; a third channel structure disposed in an overlapping region in which the first channel hole and the second channel hole overlap with each other; and a third memory layer extending along a sidewall of the third channel structure.

In accordance with still another embodiment of the present disclosure, there is provided a method of manufacturing a semiconductor memory device, the method including: forming a first channel hole penetrating a stack structure; forming a preliminary memory layer along a surface of the first channel hole; forming a preliminary channel layer on the preliminary memory layer; forming a second channel hole intersecting the first channel hole, the second channel hole penetrating the preliminary memory layer and the preliminary channel layer; forming a memory layer inside the second channel hole; and forming a channel layer disposed inside the second channel hole, the channel layer extending along a surface of the memory layer.

### BRIEF DESCRIPTION OF THE DRAWINGS

Examples of embodiments will now be described more fully hereinafter with reference to the accompanying drawings; however, they may be embodied in different forms and should not be construed as being limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. It will be understood that when an element, structure, or layer etc., is referred to as being “on,” “connected to” or “coupled to” another element, structure, or layer etc., it can be directly on, connected or coupled to the other element, structure, or layer etc., or intervening element, structure, or layer etc., may be present. In contrast, when an element, structure, or layer etc., is referred to as being “directly on,” “directly connected to” or “directly coupled to” another element, structure, or layer etc., there are no intervening element, structure, or layer etc., present. Like reference numerals refer to like elements throughout.

FIG. 1 is a block diagram schematically illustrating a semiconductor memory device in accordance with an embodiment of the present disclosure.

FIG. 2 is a circuit diagram schematically illustrating a memory cell array in accordance with an embodiment of the present disclosure.

FIGS. 3A and 3B are views schematically illustrating vertical arrangements of a semiconductor memory device in accordance with embodiments of the present disclosure.

FIGS. 4A, 4B, and 4C are plan views illustrating a semiconductor memory device in accordance with embodiments of the present disclosure.

FIGS. 5A, 5B, and 5C are views illustrating a semiconductor memory device in accordance with an embodiment of the present disclosure.

FIGS. 6A and 6B are sectional views illustrating a semiconductor memory device in accordance with an embodiment of the present disclosure.

FIG. 7 is a plan view illustrating a semiconductor memory device in accordance with embodiments of the present disclosure.

FIGS. 8, 10, 12, 14, and 16 are process plan views illustrating a manufacturing method of a semiconductor memory device in accordance with embodiments of the present disclosure.

FIGS. 9A, 9B, 11A, 11B, 13A, 13B, 15A, 15B, 17A, 17B, 18A, 18B, 19A, 19B, 20A, 20B, 21A, and 21B are process sectional views illustrating a manufacturing method of a semiconductor memory device in accordance with an embodiment of the present disclosure.

FIGS. 22A, 22B, 23A, 23B, 24A, 24B, 25A, 25B, 26A, and 26B are process sectional views illustrating a manufacturing method of a semiconductor memory device in accordance with an embodiment of the present disclosure.

FIG. 27 is a block diagram illustrating a configuration of a memory system in accordance with an embodiment of the present disclosure.

FIG. 28 is a block diagram illustrating a configuration of a computing system in accordance with an embodiment of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first,” “second,” etc. may be used herein to describe various elements, these elements should not be limited by these terms. These terms are used for distinguishing one element from another element and not to suggest a number or order of elements.

Some embodiments provide a semiconductor memory device and a manufacturing method of a semiconductor memory device, which can improve the degree of integration of memory cells.

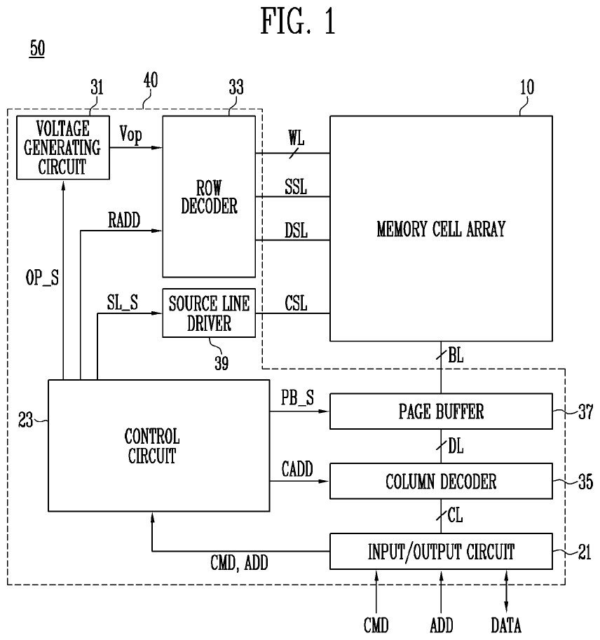

FIG. 1 is a block diagram schematically illustrating a semiconductor memory device in accordance with an embodiment of the present disclosure.

Referring to FIG. 1, the semiconductor memory device 50 may include a peripheral circuit structure 40 and a memory cell array 10.

The peripheral circuit structure 40 may be configured to perform a program operation for storing data in the memory cell array 10, a read operation for outputting data stored in the memory cell array 10, and an erase operation for erasing data stored in the memory cell array 10. In an embodiment, the peripheral circuit structure 40 may include an input/output circuit 21, a control circuit 23, a voltage generating circuit 31, a row decoder 33, a column decoder 35, a page buffer 37, and a source line driver 39.

The memory cell array 10 may be connected to the peripheral circuit structure 40 through a common source line, a bit line BL, a drain select line DSL, a word line WL, and a source select line SSL.

The input/output circuit 21 may transfer, to the control circuit 23, a command CMD and an address ADD, which received from an external device (e.g., a memory controller) of the semiconductor memory device 50. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operating voltages Vop used for a program operation, a read operation, and an erase operation in response to the operation signal OP_S.

The row decoder 33 may transfer the operating voltages Vop to the drain select line DSL, the word line WL, and the source select line

SSL in response to the row address RADD.

The column decoder 35 may transmit data DATA input from the input/output circuit 21 to the page buffer 37 or transmit data DATA stored in the page buffer 37 to the input/output circuit 21 in response to the column address CADD. The column decoder 35 may exchange data

DATA with the input/output circuit 21 through a column line CL. The column decoder 35 may exchange data DATA with the page buffer through a data line DL.

The page buffer 37 may temporarily store data DATA received through the bit line BL in response to the page buffer control signal PB_S. The page buffer 37 may sense a voltage or current of the bit line BL in a read operation.

The source line driver 39 may control a voltage applied to the common source line CSL in response to the source line control signal SL_S.

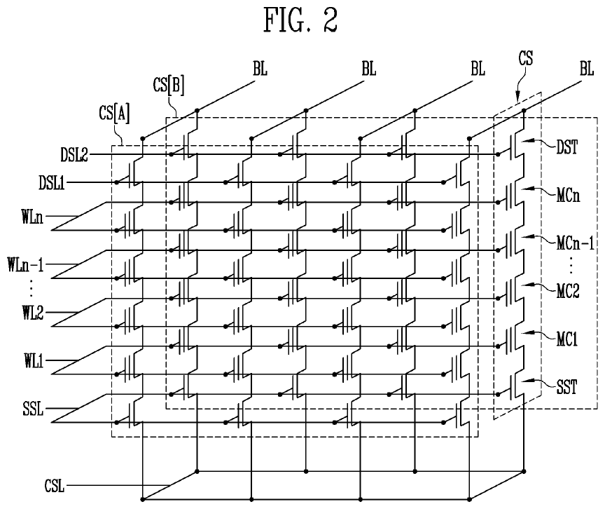

FIG. 2 is a circuit diagram schematically illustrating a memory cell array in accordance with an embodiment of the present disclosure.

Referring to FIG. 2, the memory cell array may include a plurality of memory cell strings CS.

Each memory cell string CS may include at least one source select transistor SST, a plurality of memory cells MC1 to MCn, and at least one drain select transistor DST. The plurality of memory cells MC1 to MCn may be connected in series between the source select transistor SST and the drain select transistor DST. The source select transistor SST, the plurality of memory cells MC1 to MCn, and the drain select transistor DST may be connected in series by a channel structure.

The plurality of memory cell strings CS may be connected in parallel to a common source line CSL. Each memory cell string CS may be connected to a bit line corresponding thereto among a plurality of bit lines BL. The common source line CSL and the plurality of bit lines BL may be connected to a plurality of channel structures of the plurality of cell strings CS.

The plurality of memory cells MC1 to MCn of each memory cell string CS may be connected to the common source line CSL via the source select transistor SST. The plurality of memory cells MC1 to MCn of each memory cell string CS may be connected to a bit line BL corresponding thereto via the drain select transistor DST.

The memory cell string CS may be connected to a source select line SSL, a plurality of word lines WL1 to WLn, and a drain select line DSL1 or DSL2. The source select line SSL may be used a gate electrode of the source select transistor SST. The plurality of word lines WL1 to WLn may be used as gate electrodes of the plurality of memory cells MC1 to MCn. The drain select line DSL1 or DSL2 may be used as a gate electrode of the drain select transistor DST.

The plurality of memory cell strings CS may be controlled by each of the plurality of word lines WL1 to WLn. The number of memory cell strings controlled by each bit line BL may be two or more. In an embodiment, one memory cell string of a first memory cell string group CS[A] and one memory cell string of a second memory cell string group CS[B] may be connected to each bit line BL. The first memory cell string group CS[A] and the second memory cell string group CS[B] may be individually controlled by drain select lines isolated from each other or source select lines isolated from each other. In an embodiment, the first memory cell string group CS[A] may be connected to a first drain select line DSL1, and the second memory cell string group CS[B] may be connected to a second drain select line DSL2. The first memory cell string group CS[A] and the second memory cell string group CS[B] may be connected to the same source select line SSL. Hereinafter, for convenience of description, structures of semiconductor memory devices in accordance with various embodiments of the present disclosure are described based on the example shown in FIG. 2, but the embodiment of the present disclosure is not limited thereto. In another embodiment, two or more memory cell string groups connected to the same bit line BL may be connected to the same drain select line, and be respectively connected to two or more source select lines isolated from each other. In still another embodiment, two or more memory cell string groups connected to the same bit line BL may be respectively connected to two or more drain select lines isolated from each other, and be respectively connected to two or more source select lines isolated from each other.

An operating voltage for precharging a channel structure of a memory cell string CS corresponding to each bit line BL may be applied to the bit line BL. The bit line BL may be connected to the channel structure of the memory cell string CS through a bit line contact.

An operating voltage for discharging a potential of the channel structure of the memory cell string CS may be applied to the common source line CSL. The common source line CSL may be connected to the memory cell string CS through a doped semiconductor structure.

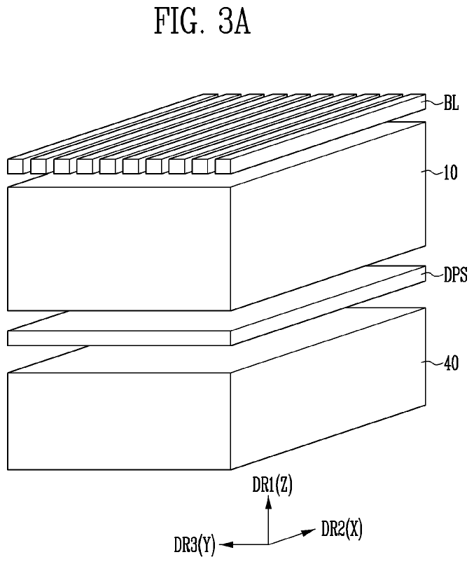

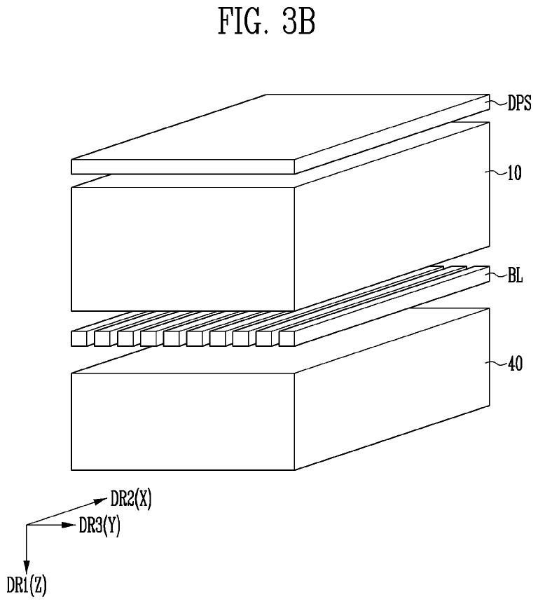

FIGS. 3A and 3B are views schematically illustrating vertical arrangements of a semiconductor memory device in accordance with embodiments of the present disclosure.

Referring to FIGS. 3A and 3B, the semiconductor memory device may include a doped semiconductor structure DSP, a memory cell array 10, and a plurality of bit lines BL. The doped semiconductor structure DPS may face the plurality of bit lines BL in a first direction DR1.

In an embodiment, the first direction DR1 may be a Z-axis direction. The doped semiconductor structure DSP may be connected to the common source line CSL shown in FIG. 2. The memory cell array 10 may be disposed between the plurality of bit lines BL and the doped semiconductor structure DPS.

Referring to FIG. 3A, a peripheral circuit structure 40 of the semiconductor memory device may be adjacent to the doped semiconductor structure DPS. Although not shown in the drawing, a plurality of interconnections may be disposed between the peripheral circuit structure 40 and the doped semiconductor structure DPS, or a plurality of interconnections and a plurality of conductive bonding pads may be disposed between the peripheral circuit structure 40 and the doped semiconductor structure DPS.

Referring to FIG. 3B, the peripheral circuit structure 40 of the semiconductor memory device may be adjacent to the plurality of bit lines BL. Although not shown in the drawing, a plurality of interconnections may be disposed between the peripheral circuit structure 40 and the plurality of bit lines BL, or a plurality of interconnections and a plurality of conductive bonding pads may be disposed between the peripheral circuit structure 40 and the plurality of bit lines BL.

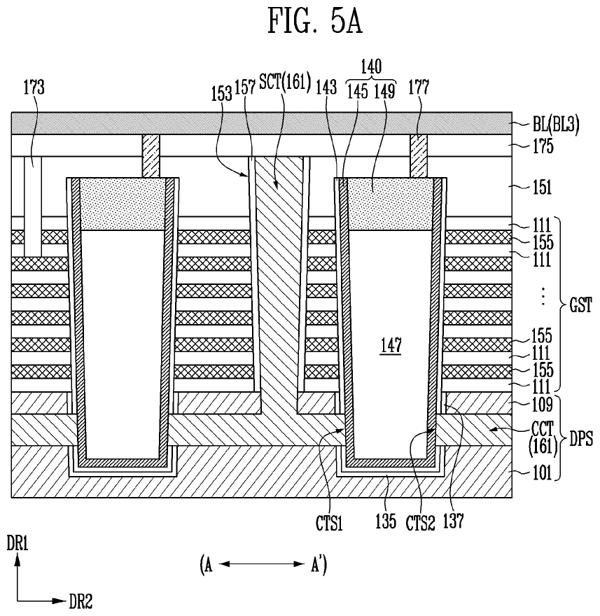

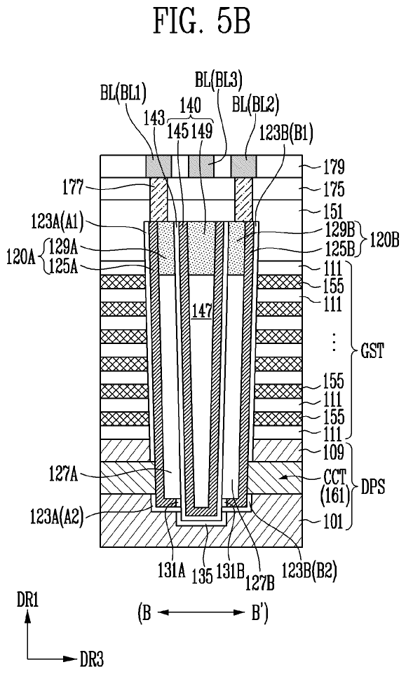

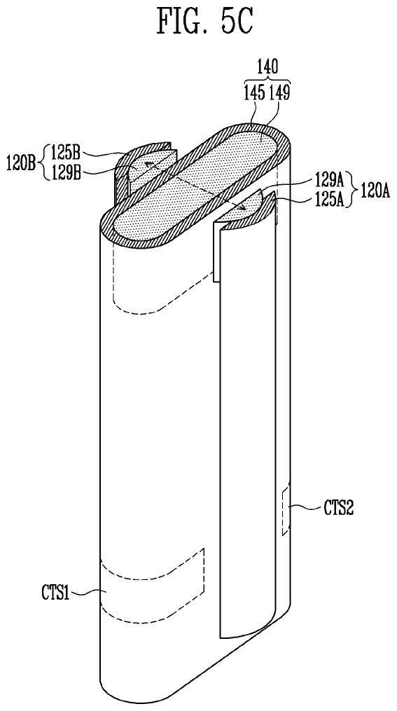

Referring to FIGS. 3A and 3B, the doped semiconductor structure DPS, the memory cell array 10, and the plurality of bit lines BL may overlap with the peripheral circuit structure 40. A plurality of channel structures of the memory cell array 10 may include first, second and third channel layers 125A, 125B, and 145 shown in FIGS. 5A and 5B, and extend in the first direction DR1. The plurality of bit lines BL may extend in parallel to one another on a plane intersecting the plurality of channel structures. In an embodiment, the plurality of bit lines BL may extend in parallel to one another on an XY plane. Hereinafter, a direction in which the plurality of bit lines BL extend may be defined as a second direction DR2, and a direction intersecting the plurality of bit lines BL may be defined as a third direction DR3. In an embodiment, the second direction DR2 may be an X-axis direction, and the third direction DR3 may be a Y-axis direction.

A process for forming the memory cell array 10 may be performed in various manners. In an embodiment, the process for forming the memory cell array 10 may be performed on the peripheral circuit structure 40. In another embodiment, a first structure including the memory cell array 10 may be formed separately from a second structure including the peripheral circuit structure 40. The first structure and the second structure may be bonded to each other through a plurality of conductive bonding pads.

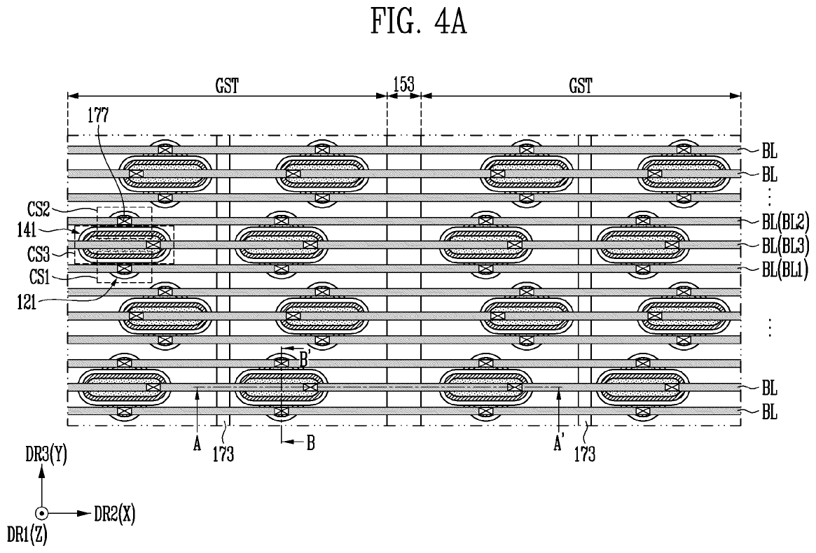

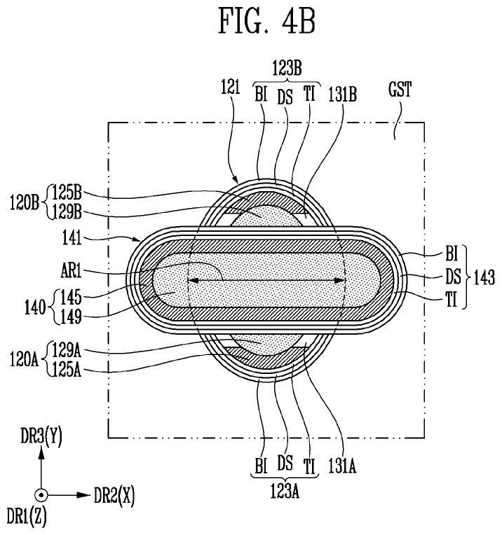

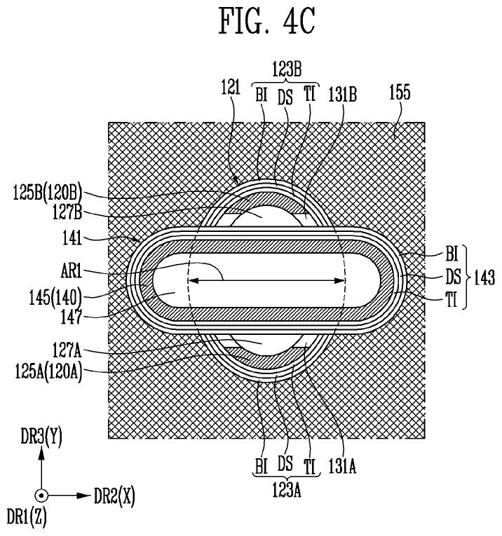

FIGS. 4A, 4B, and 4C are plan views illustrating a semiconductor memory device in accordance with embodiments of the present disclosure.

FIG. 4A is a plan view illustrating a layout of a plurality of memory cell strings CS1, CS2, and CS3, a gate stack structure GST, and a plurality of bit lines BL in accordance with an embodiment of the present disclosure.

Referring to FIG. 4A, the semiconductor memory device may include a plurality of gate stack structures GST and a plurality of bit lines BL.

The plurality of gate stack structures GST may be partitioned by a slit 153. Each gate stack structure GST may include a plurality of conductive layers 155 stacked to be spaced apart from each other in the first direction DR1 as shown in FIG. 5A. Each conductive layer 155 may have a flat plate shape extending in the second direction DR2 and the third direction DR3. The plurality of conductive layers 155 may be used as at least one source select line SSL, a plurality of word lines WL1 to WLn, at least one first drain select line DSL1, and at least one second drain select line DSL2, which are shown in FIG. 2. At least one layer among the plurality of conductive layers 155 of the gate stack structure GST may be penetrated by a line isolation structure 173. In an embodiment, the line isolation structure 173 may be provided to isolate at least one layer among the plurality of conductive layers into a first drain select line DSL1 and a second drain select line DSL2 as shown in FIG. 2.

The gate stack structure GST may include a plurality of channel holes 121 and 141. The plurality of channel holes 121 and 141 may extend in the first direction DR1, to penetrate the gate stack structure GST. The plurality of channel holes 121 and 141 may include a first channel hole 121 ad a second channel hole 141, which intersect each other.

A cell plug structure for at least three memory cell strings among the plurality of memory cell strings CS1, CS2, and CS3 may be disposed inside the first channel hole 121 and the second channel hole 141. In an embodiment, a cell plug structure for a first memory cell string CS1, a second memory cell string CS2, and a third memory cell string CS3 may be disposed inside the first channel hole 121 and the second channel hole 141.

The cell plug structure may include a first channel structure and a first memory layer, which are used for the first memory cell strings CS1, a second channel structure and a second memory layer, which are used for the second memory cell string CS2, and a third channel structure and a third memory layer, which are used for the third memory cell string CS3. The first to third channel structures and the first to third memory layers will be described later with reference to FIGS. 4B and 4C. Positions of the first memory cell string CS1 and the second memory cell string CS2 may be associated with positions of both ends of the first channel hole 121, and a position of the third memory cell string CS3 may be associated with a position of the second channel hole 141. The third memory cell string CS3 may be disposed between the first memory cell string CS1 and the second memory cell string CS2.

The plurality of bit lines BL may be connected to the plurality of memory cell strings CS1, CS2, and CS3 through a plurality of bit line contacts 177. The plurality of bit lines BL may include a first bit line BL1 connected to the first memory cell string CS1, a second bit line BL2 connected to the second memory cell string CS2, and a third bit line BL3 connected to the third memory cell string CS3.

Both ends of the first channel hole 121 may further protrude than the second channel hole 141 in directions opposite to each other on an XY plane. An arrangement order of the first bit line BL1, the second bit line BL2, and the third bit line BL3 may be changed according to both the ends of the first channel hole 121 and the second channel hole 141. In an embodiment, both the ends of the first channel hole 121 may further protrude than the second channel hole 141 in a direction intersecting the plurality of bit lines BL. In accordance with this embodiment, the first memory cell string CS1 and the second memory cell string CS2 may be adjacent to each other in the third direction DR3 with the third memory cell string CS3 interposed therebetween, and may be adjacent to each other in the third direction DR3 with the first bit line BL1, the second bit line BL2, and the third bit line BL3, which are interposed therebetween.

FIGS. 4B and 4C are plan views illustrating a cell plug structure disposed inside the first channel hole and the second channel hole, which are shown in FIG. 4A. FIG. 4B is an enlarged view illustrating a top surface of the cell plug structure, which faces the plurality of bit lines BL shown in FIGS. 4A, and 4C illustrates a plan view of the cell plug structure taken along an XY plane at a level at which one of the plurality of conductive layers 155 of the gate stack structure GST shown in FIG. 4A.

Referring to FIGS. 4B and 4C, the cell plug structure may include a first memory layer 123A, a second memory layer 123B, a third memory layer 143, a first channel structure 120A, a second channel structure 120B, and a third channel structure 140. The first memory layer 123A, the second memory layer 123B, the third memory layer 143, the first channel structure 120A, the second channel structure 120B, and the third channel structure 140 may extend in the first direction DR1.

The first memory layer 123A and the second memory layer 123B may be disposed at both ends of the first channel hole 121 further protruding than the second channel hole 141. The first channel hole 121 and the second channel hole 141 overlap with each other in an overlapping region AR1. Both the ends of the first channel hole 121 may be portions protruding from the overlapping region AR1 to both sides of the overlapping region AR1. The first memory layer 123A and the second memory layer 123B may be isolated from each other by the second channel hole 141. The first memory layer 123A and the second memory layer 123B may extend along a sidewall of the first channel hole 121.

The first channel structure 120A and the second channel structure 120B may be disposed inside the first channel hole 121, and be isolated from each other by the second channel hole 141. The first channel structure 120A and the second channel structure 120B may be disposed at both the ends of the first channel hole 121. The first channel structure 120A may include a first channel layer 125A and a first capping doped semiconductor layer 129A. The second channel structure 120B may include a second channel layer 125B and a second capping doped semiconductor layer 129B.

The first channel layer 125A may extend along an inner sidewall of the first memory layer 123A. The second channel layer 125B may extend along an inner sidewall of the second memory layer 123B. The first channel layer 125A and the second channel layer 125B may be isolated from each other by the second channel hole 141.

The first capping doped semiconductor layer 129A and a first core insulating layer 127A may be disposed in a portion of the first channel hole 121, which is adjacent to the overlapping region AR1. The second capping doped semiconductor layer 129B and a second core insulating layer 127B may be disposed in another portion of the first channel hole 121, which is adjacent to the overlapping region AR1. The first core insulating layer 127A and the second core insulating layer 127B may be isolated from each other by the second channel hole 141. The first capping doped semiconductor layer 129A and the second capping doped semiconductor layer 129B, which are shown in FIG. 4B, may overlap with the first core insulating layer 127A and the second core insulating layer 127B, which are shown in FIG. 4C.

The first channel layer 125A may extend between the first core insulating layer 127A and the first memory layer 123A from between the first capping doped semiconductor layer 129A and the first memory layer 123A. The second channel layer 125B may extend between the second core insulating layer 127B and the second memory layer 123B from between the second capping doped semiconductor layer 129B and the second memory layer 123B.

The third channel structure 140 may be disposed between the first channel structure 120A and the second channel structure 120B, and may be disposed in the overlapping region AR1. The third memory layer 143 may extend along a sidewall of the third channel structure 140.

The second channel hole 141 may include both ends further protruding laterally than the first channel hole 121. The third channel structure 140 and the third memory layer 143 may extend toward both the ends of the second channel hole 141. Accordingly, the third channel structure 140 may further protrude laterally than the first channel structure 120A and the second channel structure 120B. In an embodiment, the third channel structure 140 may further protrude in an extending direction (e.g., DR2) of the plurality of bit lines shown in FIG. 4A than the first channel structure 120A and the second channel structure 120B, and the third memory layer 143 may further protrude in the extending direction DR2 of the plurality of bit lines shown in FIG. 4A than the first memory layer 123A and the second memory layer 123B.

The third memory layer 143 may extend to surround the sidewall of the third channel structure 140. In an embodiment, the third memory layer 143 may be in contact with the first memory layer 123A and the second memory layer 123B to form a common plane with each of the first memory layer 123A and the second memory layer 123B as shown in FIGS. 4B and 4C.

The third channel structure 140 may include a third channel layer 145 and a third capping doped semiconductor layer 149. The third channel layer 145 may extend along an inner sidewall of the third memory layer 143. The third capping doped semiconductor layer 149 may be disposed in a central region of the second channel hole 141 surrounded by the third channel layer 145. A third core insulating layer 147 may be further disposed in the central region of the second channel hole 141. The third capping doped semiconductor layer 149 shown in FIG. 4B may overlap with the third core insulating layer 147 shown in FIG. 4C. The third channel layer 145 may extend between the third core insulating layer 147 and the third memory layer 143 from between the third capping doped semiconductor layer 149 and the third memory layer 143.

The first channel structure 120A, the second channel structure 120B, and the third channel structure 140 may be surrounded by the gate stack structure GST shown in FIG. 4A. The third channel structure 140 may be spaced apart from the first channel structure 120A and the second channel structure 120B without interposition of a conductive layer 155 shown in FIG. 4C. For example, the third channel structure 140 may be spaced apart from the first channel structure 120A without interposition of the conductive layer 155 between the third channel structure 140 and the first channel structure 120A. For example, the third channel structure 140 may be spaced apart from the second channel structure 120B without interposition of the conductive layer 155 between the third channel structure 140 and the second channel structure 120B.

The first memory layer 123A may be interposed between the first channel structure 120A and the conductive layer 155 shown in FIG. 4C, the second memory layer 123B may be interposed between the second channel structure 120B and the conductive layer 155 shown in FIG. 4C, and the third memory layer 143 may be interposed between the third channel structure 140 and the conductive layer 155 shown in FIG. 4C. Each of the first memory layer 123A, the second memory layer 123B, and the third memory layer 143 may include a tunnel insulating layer TI extending along an outer sidewall of a channel structure corresponding thereto, a data storage layer DS extending along an outer sidewall of the tunnel insulting layer TI, and a blocking insulating layer BI extending along an outer sidewall of the data storage layer DS. The data storage layer DS may be formed of a material layer capable of storing data changed using Fowler-Nordheim tunneling. To this end, the data storage layer DS may be formed of various materials. For example, the data storage layer DS may be formed as a charge trap layer. The charge trap layer may include a silicon nitride layer. However, the present disclosure is not limited thereto, and the data storage layer DS may include a phase change material, a nano dot, and the like. The blocking insulating layer

BI may include an insulating material capable of blocking charges. The tunnel insulating layer TI may be formed as a silicon oxide layer through which charges can tunnel.

The semiconductor memory device may include a plurality of interposition insulating layers. The plurality of interposition insulating layers may be formed of oxide. In an embodiment, the plurality of interposition insulating layers may include a first interposition insulating layer 131A and a second interposition insulating layer 131B. The first interposition insulating layer 131A may be disposed between the first channel layer 125A of the first channel structure 120A and the third memory layer 143. The second interposition insulating layer 131B may be disposed between the second channel layer 125B of the second channel structure 120B and the third memory layer 143.

One of the first channel hole 121 and the second channel hole 141 may be formed in a planar shape having a major axis along the extending direction of the plurality of bit lines BL shown in FIG. 4A, and the other of the first channel hole 121 and the second channel hole 141 may be formed in a planar shape having a major axis along the direction intersecting the plurality of bit lines BL shown in FIG. 4A. In an embodiment, on an XY plane, the first channel hole 121 may be formed in an elliptical planar shape having a major axis along the third direction DR3, and the second channel hole 141 may be formed in an elliptical planar shape having a major axis along the second direction DR2.

FIGS. 5A, 5B, and 5C are views illustrating a semiconductor memory device in accordance with an embodiment of the present disclosure.

FIG. 5A is a sectional view of the semiconductor memory device taken along line A-A′ shown in FIG. 4A, and FIG. 5B is a sectional view of the semiconductor memory device taken along line B-B′ shown in FIG. 4A.

Referring to FIGS. 5A and 5B, the semiconductor memory device may include a doped semiconductor structure DPS, a plurality of bit lines BL overlapping with the doped semiconductor structure DPS, a gate stack structure GST between the doped semiconductor structure DSP and the plurality of bit lines BL, and a first channel structure 120A, a second channel structure 120B, and a third channel structure 140, which are connected to the doped semiconductor structure DPS. Hereinafter, overlapping descriptions of the same components as those shown in FIGS. 4A to 4C will be omitted.

The gate stack structure GST may include a plurality of conductive layers 155 and a plurality of interlayer insulating layers 111, which are alternately stacked in the first direction DR1. Each conductive layer 155 may include at least one of a doped semiconductor layer, a metal layer, and a conductive metal nitride layer. The doped semiconductor layer may include a doped silicon layer. The metal layer may include tungsten, copper, molybdenum, and the like. The conductive metal nitride layer may include titanium nitride, tantalum nitride, and the like.

At least one insulating layer may be disposed between the gate stack structure GST and the plurality of bit lines BL. In an embodiment, a first insulating layer 151 and a second insulating layer 175 may be disposed between the gate stack structure GST and the plurality of bit lines BL.

At least one conductive layer adjacent to the plurality of bit lines BL among the plurality of conductive layers 155 may be penetrated by a line isolation structure 173. The line isolation structure 173 may be formed of an insulating material, and extend in the first direction DR1 to penetrate the first insulating layer 151. A sidewall insulating layer 157 may be formed on a sidewall of a slit 153 forming a common plane with the gate stack structure GST. A source contact structure SCT may be disposed inside the slit 153. The source contact structure SCT may be provided to electrically connect the doped semiconductor structure DSP to the common source line CSL shown in FIGS. 1 and 2. The source contact structure SCT may be insulated from the plurality of conductive layers 155 of the gate stack structure GST by the sidewall insulating layer 157.

The doped semiconductor structure DPS may include a lower doped semiconductor layer 101, a channel contact structure CCT, and an etch stop layer 109. The channel contact structure CCT may be disposed between the lower doped semiconductor layer 101 and the gate stack structure GST. The etch stop layer 109 may be disposed between the channel contact structure CCT and the gate stack structure GST. The etch stop layer 109 may be omitted.

The channel contact structure CCT may be formed with a doped semiconductor layer 161. Each of the lower doped semiconductor layer 101 and the doped semiconductor layer 161 may include at least one of an n-type impurity and a p-type impurity. The doped semiconductor layer 161 may extend to the inside of the slit 153 to form the source contact structure SCT. However, the embodiment of the present disclosure is not limited thereto. In another embodiment, the channel contact structure CCT may be formed with a doped semiconductor layer, and the source contact structure SCT may be formed with a metal layer. The etch stop layer 109 may be formed of a material selected by considering an etch selectivity during an etching process for forming the slit 153. In an embodiment, the etch stop layer 109 may include a silicon layer.

A first memory layer 123A, a second memory layer 123B, a third memory layer 143, a first channel layer 125A, a second channel layer 125B, a third channel layer 145, a first core insulating layer 127A, a second core insulating layer 127B, and a third core insulating layer 147 may extend to the inside of the lower doped semiconductor layer 101. A first capping doped semiconductor layer 129A, a second capping doped semiconductor layer 129B, a third capping doped semiconductor layer 149 may respectively overlap with the first core insulating layer 127A, the second core insulating layer 127B, and the third core insulating layer 147.

The third channel structure 140 may further protrude to the inside of the lower doped semiconductor layer 101 than the first channel structure 120A and the second channel structure 120B. More specifically, the third channel layer 145 may further protrude to the inside of the lower doped semiconductor layer 101 than the first channel layer 125A and the second channel layer 125B.

FIG. 5C is a perspective view illustrating the first channel structure 120A, the second channel structure 120B, and the third channel structure 140, which are shown in FIGS. 5A and 5B.

Referring to FIG. 5C, the third channel structure 140 may be formed longer than the first channel structure 120A and the second channel structure 120B. The first channel layer 125A, the second channel layer 125B, and the third channel layer 145 may be formed longer than the first capping doped semiconductor layer 129A, the second capping doped semiconductor layer 129B, and the third capping doped semiconductor layer 149. The third channel layer 145 may be formed longer than the first channel layer 125A and the second channel layer 125B.

Referring to FIGS. 5A and 5B, the channel contact structure CCT may be in contact with a sidewall of each of the first channel structure 120A, the second channel structure 120B, and the third channel structure 140. More specifically, the channel contact structure CCT may protrude toward the first channel layer 125A, the second channel layer 125B, and the third channel layer 145 to penetrate the first memory layer 123A, the second memory layer 123B, and the third memory layer 143, and be in contact with the first channel layer 125A, the second channel layer 125B, and the third channel layer 145.

The sidewall of each of the first channel layer 125A and the second channel layer 125B may be surrounded by the channel contact structure CCT. The first memory layer 123A may be isolated into an upper first memory layer A1 and a lower first memory layer A2 by the channel contact structure CCT. The second memory layer 123B may be isolated into an upper second memory layer B1 and a lower second memory layer B2 by the channel contact structure CCT.

The channel contact structure CCT may be in contact with a portion of the sidewall of the third channel layer 145. In an embodiment, the third channel layer 145 may include a first contact surface CTS1 and a second contact surface CTS2, which are in contact with the channel contact structure CCT. The first contact surface CTS1 and the second contact surface CTS2 may be portions of the third channel layer 145 extending to the outside of the overlapping region AR1 shown in FIGS. 4B and 4C.

Referring to FIG. 5C, the first contact surface CTS1 and the second contact surface CTS of the third channel layer 145 may be spaced apart from each other, and the third memory layer 143 shown in FIGS. 5A and 5B may extend along a sidewall of the third channel layer 145 between the first contact surface CTS1 and the second contact surface CTS2.

Referring to FIGS. 5A and 5B, the third memory layer 143 may continuously extend along a bottom surface of the third channel layer 145, which faces in the direction opposite to the first direction DR1, from the sidewall of the third channel layer 145 between the first contact surface CTS1 and the second contact surface CTS2.

A plurality of bit line contacts 177 may extend to penetrate the first insulating layer 151 and the second insulating layer 175 from the first channel structure 120A, the second channel structure 120B, and the third channel structure 140.

The plurality of bit lines BL may penetrate a third insulating layer 179 on the second insulating layer 175.

The plurality of interposition insulating layers described with reference to FIGS. 4B, and 4C may further include a first lower interposition insulating layer 135 and a second lower interposition insulating layer 137. The first lower interposition insulating layer 135 may be disposed between the lower doped semiconductor layer 101 and the third memory layer 143. The second lower interposition insulating layer 137 may be disposed between the etch stop layer 109 and the third memory layer 143.

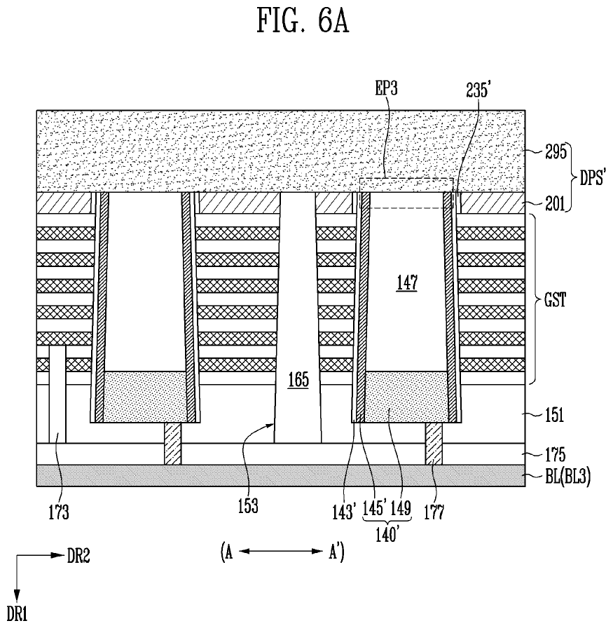

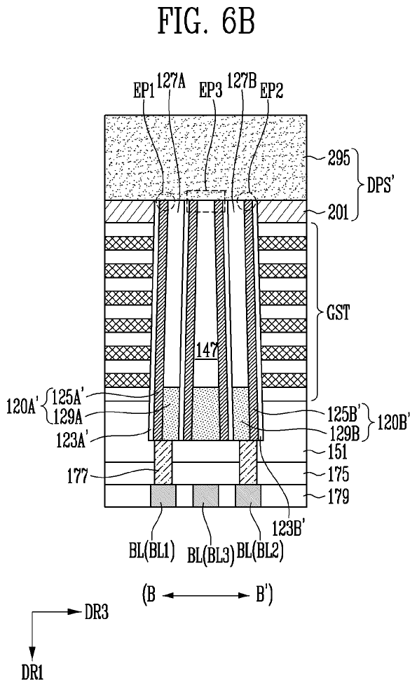

FIGS. 6A and 6B are sectional views illustrating a semiconductor memory device in accordance with an embodiment of the present disclosure. FIG. 6A is a sectional view of the semiconductor memory device taken along the line A-A′ shown in FIG. 4A, and FIG. 6B is a sectional view of the semiconductor memory device taken along the line B-B′ shown in FIG. 4A. Hereinafter, overlapping descriptions of the same components as those shown in FIGS. 4A to 4C and 5A and 5B will be omitted.

Referring to FIGS. 6A and 6B, the semiconductor memory device may include a gate stack structure GST, a line isolation structure 173, a slit 153, a plurality of bit lines BL, a first insulating layer 151, a second insulating layer 175, and a third insulating layer 179 as described with reference to FIGS. 5A and 5B.

A doped semiconductor structure DPS′ may include a doped semiconductor layer 295. The doped semiconductor structure DPS′ may further include a semiconductor substrate 201 disposed between the doped semiconductor layer 295 and the gate stack structure GST. Each of the doped semiconductor layer 295 and the semiconductor substrate 201 may include at least one of an n-type impurity and a p-type impurity.

The gate stack structure GST may include the first channel hole 121 and the second channel hole 141, which are shown in FIG. 4A.

The first channel hole 121 and the second channel hole 141, which are shown in FIG. 4A may be filled with a cell plug structure shown in FIGS. 6A and 6B. The cell plug structure shown in FIGS. 6A and 6B may include a first memory layer 123A′, a second memory layer 123B′; a third memory layer 143′, a first channel structure 120A′, a second channel structure 120B′; a third channel structure 140′, a first core insulating layer 127A, a second core insulating layer 127B, and a third core insulating layer 147. The above-described cell plug structure may further protrude toward the doped semiconductor layer 295 than the gate stack structure GST. The semiconductor substrate 201 may surround a sidewall of a protrusion part of the cell plug structure, which further protrudes than the gate stack structure GST.

A first capping doped semiconductor layer 129A of the first channel structure 120A′, a second capping doped semiconductor layer 129B of the second channel structure 120B′, and a third capping doped semiconductor layer 149 of the third channel structure 140′ may be configured the same as those described with reference to FIGS. 5A and 5B. A first channel layer 125A′ of the first channel structure 120A′, a second channel layer 125B′ of the second channel structure 120B′; and a third channel layer 145′ of the third channel structure 140′ may be in contact with the doped semiconductor layer 295. Ends EP1, EP2, and EP3 of the first channel layer 125A′, the second channel layer 125B′, and the third channel layer 145′ may be in contact with the doped semiconductor layer 295.

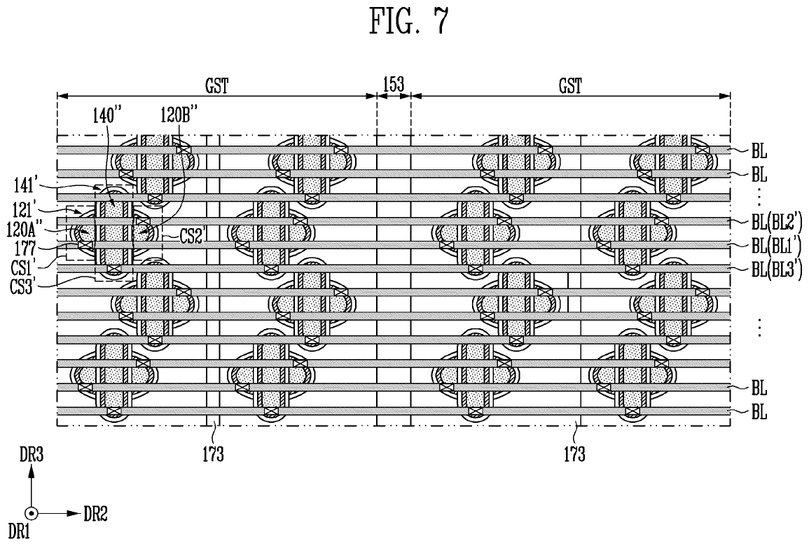

FIG. 7 is a plan view illustrating a semiconductor memory device in accordance with embodiments of the present disclosure. Hereinafter, overlapping descriptions of the same components as those shown in FIGS. 4A to 4C will be omitted.

Referring to FIG. 7, the semiconductor memory device may include a gate stack structure GST and a plurality of bit lines BL. The gate stack structure GST may be partitioned by a slit 153 and include a line isolation structure 173. The plurality of bit lines BL overlapping with the gate stack structure GST.

The gate stack structure GST may be penetrated by a first channel hole 121′ and a second channel hole 141′. The first channel hole 121′ and the second channel hole 141′ may intersect each other and extend in the first direction DR1. Both ends of the first channel hole 121′ may further protrude in an extending direction of the plurality of bit lines

BL than the second channel hole 141′. The second channel hole 141′ may further protrude in a direction intersecting the plurality of bit lines BL than the first channel hole 121′. In an embodiment, the first channel hole 121′ may be formed in an elliptical shape having a major axis along the second direction DR2. The second channel hole 141′ may be formed in an elliptical shape having a major axis along the third direction DR3.

In accordance with the above-described embodiment, a first channel structure 120A″ and a second channel structure 120B″, which are disposed at both the ends of the first channel hole 121′, may be adjacent to each other in the second direction DR2. A third channel structure 140″ may further protrude in the third direction DR3 than the first channel structure 120A″ and the second channel structure 120B″.

The plurality of bit lines BL may include a first bit line BL1′, a second bit line BL2′, and a third bit line BL3′. The first bit line BL1′ may be connected to the first channel structure 120A″ through a bit line contact 177, the second bit line BL2′ may be connected to the second channel structure 120B″ through another bit line contact 177, and the third bit line BL3′ may be connected to the third channel structure 140″ through still another bit line contact 177. The first bit line BL1′, the second bit line BL2′, and the third bit line BL3′, which are disposed consecutively, may overlap with the third channel structure 140″. The first bit line BL1′ may be disposed between the second bit line BL2′ and the third bit line BL3′.

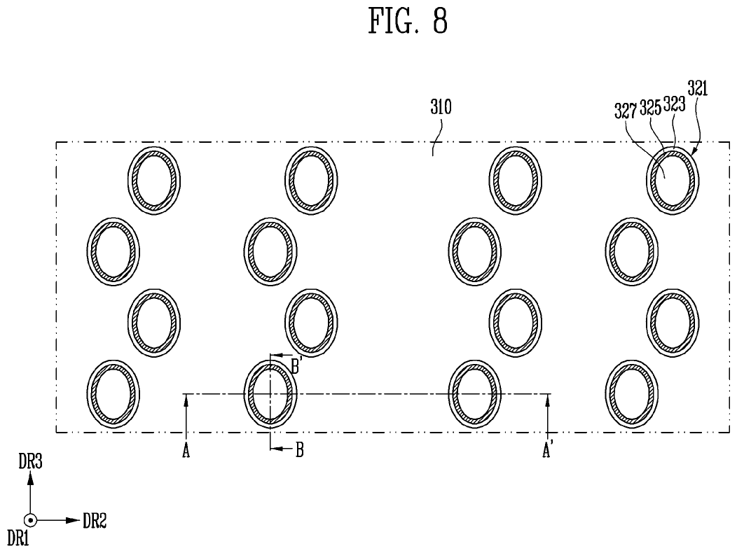

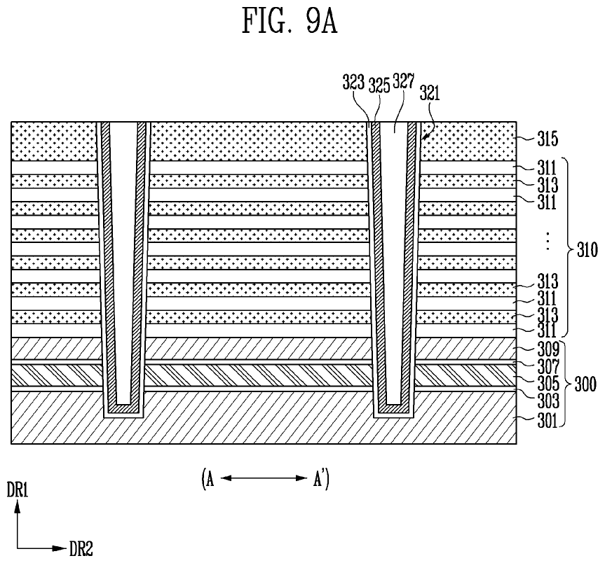

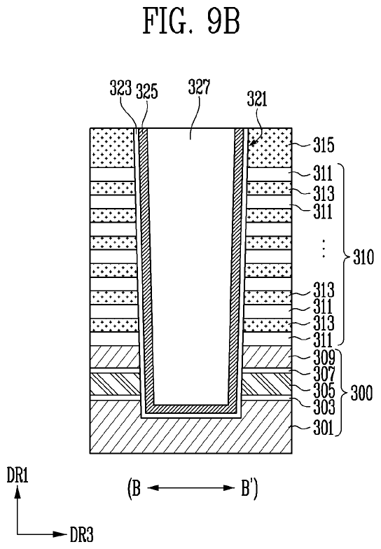

FIGS. 8, 10, 12, 14, and 16 are process plan views illustrating a manufacturing method of a semiconductor memory device in accordance with embodiments of the present disclosure. FIGS. 9A, 9B, 11A, 11B, 13A, 13B, 15A, 15B, 17A, 17B, 18A, 18B, 19A, 19B, 20A, 20B, 21A, and 21B are process sectional views illustrating a manufacturing method of a semiconductor memory device in accordance with an embodiment of the present disclosure.

FIG. 8 is a plan view illustrating a process of forming a first channel hole, a preliminary memory layer, and a preliminary channel layer. FIG. 9A is a sectional view taken along line A-A′ shown in FIG. 8, and FIG. 9B is a sectional view tank along line B-B′ shown in FIG. 8.

Referring to FIGS. 8, 9A, and 9B, a first channel hole 321 may be formed to penetrate the stack structure 310. In an embodiment, the stack structure 310 may be disposed on a preliminary doped semiconductor structure 300.

The preliminary doped semiconductor structure 300 may include a lower doped semiconductor layer 301, a first protective layer 303 on the lower doped semiconductor layer 301, and a sacrificial layer 305 on the first protective layer 303. The preliminary doped semiconductor structure 300 may further include an etch stop layer 309 on the sacrificial layer 305, and further include a second protective layer 307 between the sacrificial layer 305 and the etch stop layer 309. The first protective layer 303 and the second protective layer 307 may be formed of a material having an etch selectivity with respect to the sacrificial layer 305. In an embodiment, the sacrificial layer 305 may be formed as an undoped silicon layer, and each of the first protective layer 303 and the second protective layer 307 may be formed as an oxide layer. The etch stop layer 309 may be formed of a material having an etch selectivity with respect to the stack structure 310. In an embodiment, the etch stop layer 309 may be formed as a semiconductor layer including silicon and the like.

The stack structure 310 may include a plurality of first material layers 311 and a plurality of second material layers 313, which are alternately stacked on the preliminary doped semiconductor structure 300. The second material layer 313 may be formed of a material different from a material of the first material layer 311. In an embodiment, the first material layer 311 may be provided as an interlayer insulating layer, and the second material layer 313 may be provided as a conductive layer. The first material layer 311 may include an insulating material including silicon oxide and the like, and the second material layer 313 may include at least one of a doped semiconductor layer, a metal layer, and a conductive metal nitride layer. In another embodiment, the first material layer 311 may be provided as an interlayer insulating layer, and the second material layer 313 may be formed of a sacrificial material having an etch selectivity with respect to the first material layer 311.

The first material layer 311 may be formed of silicon oxide, and the second material layer 313 may be formed of silicon nitride.

A mask layer 315 may be formed on the stack structure 310. The first channel hole 321 may be formed by etching the mask layer 315 and the stack structure 310, using a photolithography process.

The first channel hole 321 may penetrate the plurality of first material layers 311 and the plurality of second material layers 313 of the stack structure 310, and extend to the inside of the preliminary doped semiconductor structure 300. In an embodiment, the first channel hole 321 may penetrate the first protective layer 303, the sacrificial layer 305, the second protective layer 307, and the etch stop layer 309, and extend to the inside of the lower doped semiconductor layer 301.

The first channel hole 321 may extend in the first direction DR1 to penetrate the stack structure 310, and formed in a planar shape having a major axis along the second direction DR2 or the third direction DR3 on an XY plane. Hereinafter, the manufacturing method of the semiconductor memory device is described by using, as an example, a case where the first channel hole 321 is formed in an elliptical planar shape having a major axis along the third direction DR3, but the embodiment of the present disclosure is not limited thereto. For example, the first channel hole 321 may be formed in an elliptical planar shape having a major axis along the second direction DR2, like the first channel hole 121′ shown in FIG. 7.

Subsequently, a preliminary memory layer 323 may be formed along a surface of the first channel hole 321. The preliminary memory layer 323 may include the blocking insulating layer BI, the data storage layer DS, and the tunnel insulating layer TI, which are described with reference to FIGS. 4B and 4C. Subsequently, a preliminary channel layer 325 may be formed on the preliminary memory layer 323. The preliminary channel layer 325 may be formed as a semiconductor layer including silicon, germanium, and the like. Subsequently, a preliminary core insulating layer 327 may be formed in a central region of the first channel hole 321, which is opened by the preliminary channel layer 325.

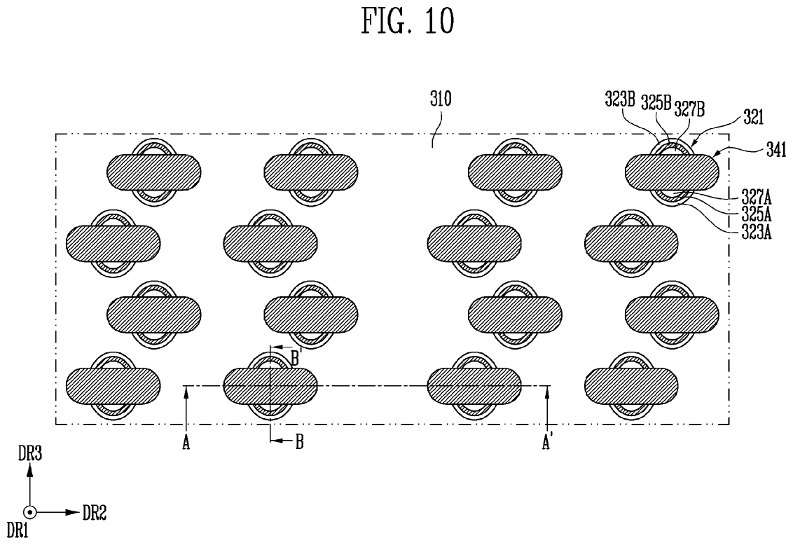

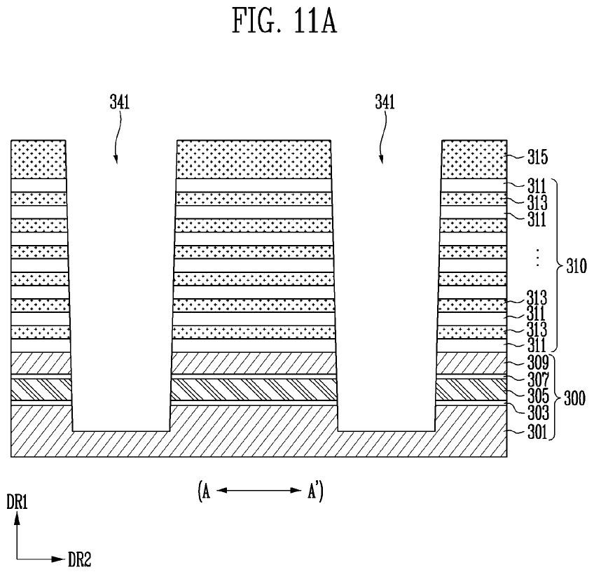

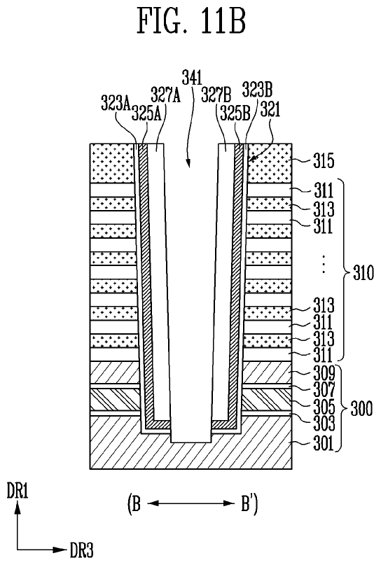

FIG. 10 is a plan view illustrating a process of forming a second channel hole. FIG. 11A is a sectional view taken along line A-A′ shown in FIG. 10, and FIG. 11B is a sectional view taken along line B-B′ shown in FIG. 10.

Referring to FIGS. 10, 11A, and 11B, a second channel hole 341 may extend in the first direction DR1 to penetrate the stack structure 310, and intersect the first channel hole 321.

The second channel hole 341 may be formed by etching the mask layer 315 and the stack structure 310, using a photolithography process. A portion of each of the preliminary insulating layer 337, the preliminary channel layer 325, and the preliminary memory layer 323, which are shown in FIGS. 8, 9A, and 9B, may be etched while the second channel hole 341 is formed. The second channel hole 341 may extend deeper to the inside of the lower doped semiconductor layer 301 than the first channel hole 321, to penetrate the preliminary core insulating layer 327, the preliminary channel layer 325, and the preliminary memory layer 323, which are shown in FIGS. 8, 9A, and 9B. Accordingly, the lower doped semiconductor layer 301 may be exposed by the second channel hole 341.

The preliminary core insulating layer 327 shown in FIGS. 8, 9A, and 9B may be isolated into a first core insulating layer 327A and a second core insulating layer 327B by the second channel hole 341. The preliminary channel layer 325 shown in FIGS. 8, 9A, and 9B may be isolated into a first channel layer 325A and a second channel layer 325B by the second channel hole 341. The preliminary memory layer 323 shown in FIGS. 8, 9A, and 9B may be isolated into a first memory layer 323A and a second memory layer 323B by the second channel hole 341.

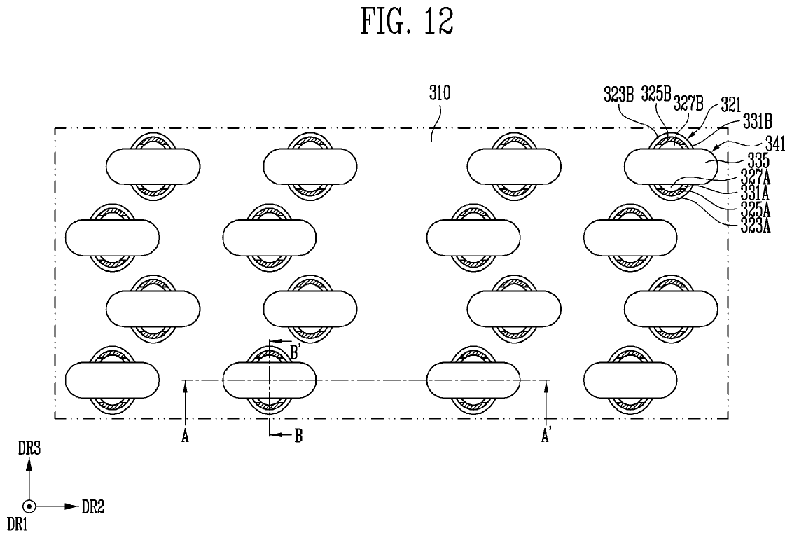

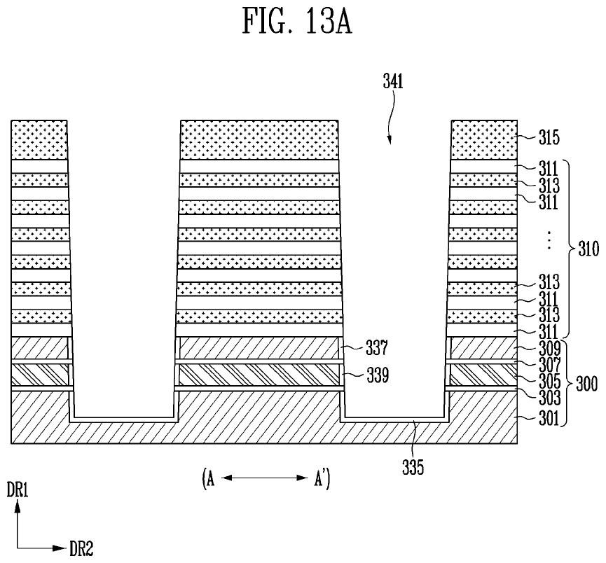

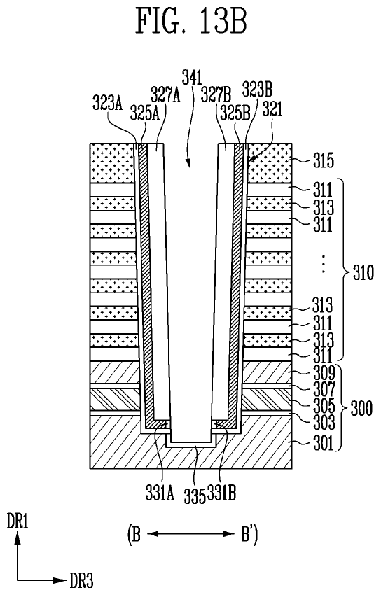

FIG. 12 is a plan view illustrating a process of forming a plurality of interposition insulating layers. FIG. 13A is a sectional view taken along line A-A′ shown in FIG. 12, and FIG. 13B is a sectional view taken along line B-B′ shown in FIG. 12.

Referring to FIGS. 12, 13A, and 13B, a portion of each of the first channel layer 325A, the second channel layer 325B, the lower doped semiconductor layer 301, the sacrificial layer 305, and the etch stop layer 309 may be oxidized through the second channel hole 341. Accordingly, a plurality of interposition insulating layers 331A, 331B, 335, 337, and 339 may be formed.

The plurality of interposition insulating layers 331A, 331B, 335, 337, and 339 may include first and second interposition insulating layers 331A and 331B and first to third lower interposition insulating layers 335, 337, and 339. The first interposition insulating layer 331A may be formed by oxidizing a portion of the first channel layer 325A. The second interposition insulating layer 331B may be formed by oxidizing a portion of the second channel layer 325B. The first lower interposition insulating layer 335 may be formed by oxidizing a portion of the lower doped semiconductor layer 301. The second lower interposition insulating layer 337 may be formed by oxidizing a portion of the etch stop layer 309. The third lower interposition insulating layer 339 may be formed by oxidizing a portion of the sacrificial layer 305.

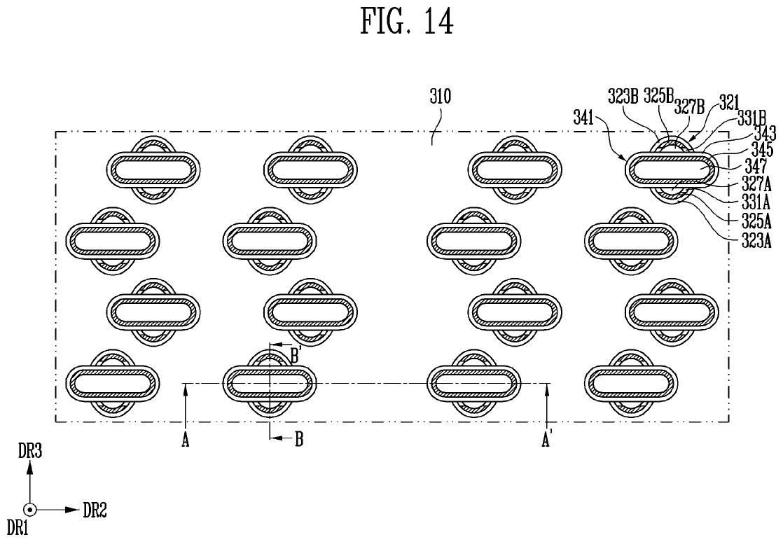

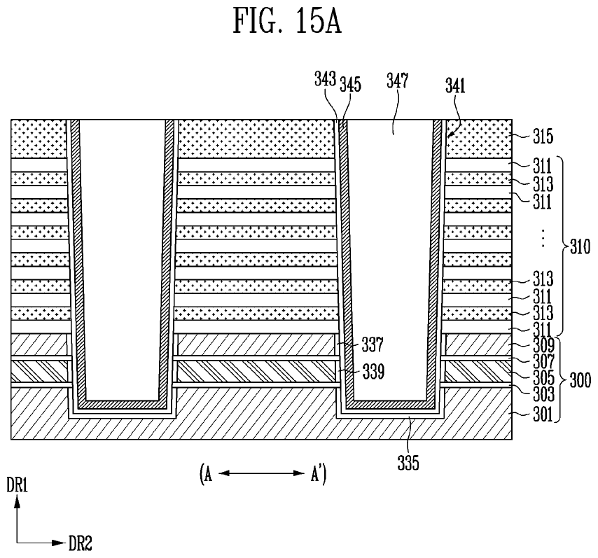

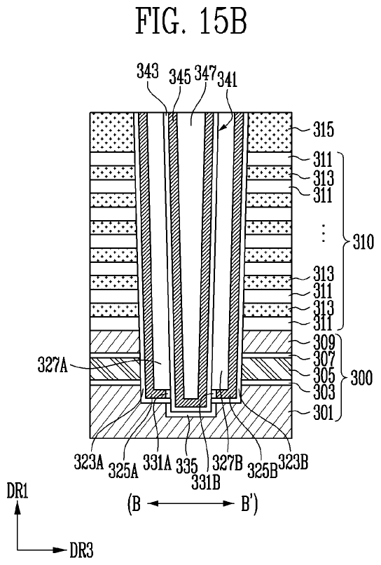

FIG. 14 is a plan view illustrating a process of forming a third memory layer, a third channel layer, and a third core insulating layer. FIG. 15A is a sectional view taken along line A-A′ shown in FIG. 14, and FIG. 15B is a sectional view taken along line B-B′ shown in FIG. 14.

Referring to FIGS. 14, 15A, and 15B, a third memory layer 343 may be formed along a surface of the second channel hole 341. The third memory layer 343 may include the blocking insulating layer BI, the data storage layer DS, and the tunnel insulating layer TI, which are described with reference to FIGS. 4B and 4C. Subsequently, a third channel layer 345 may be formed on the third memory layer 343. The third channel layer 345 may be formed as a semiconductor layer including silicon, germanium, and the like. Subsequently, a third core insulating layer 347 may be formed in a central region of the second channel hole 341, which is opened by the third channel layer 345.

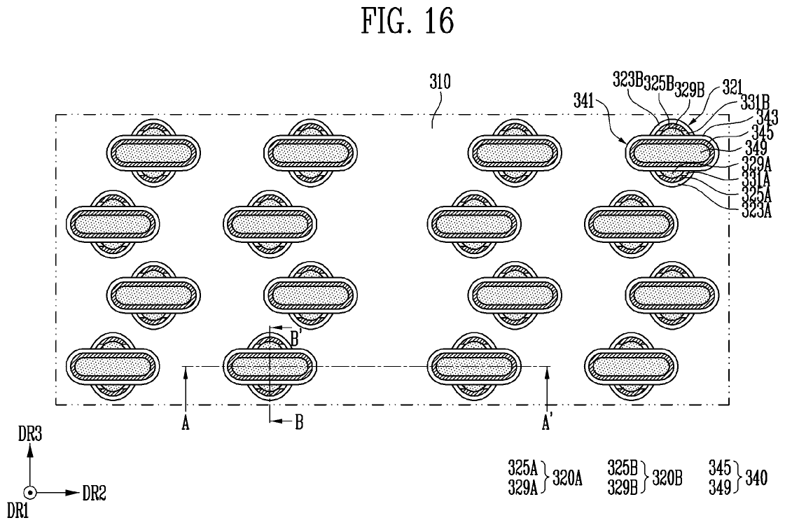

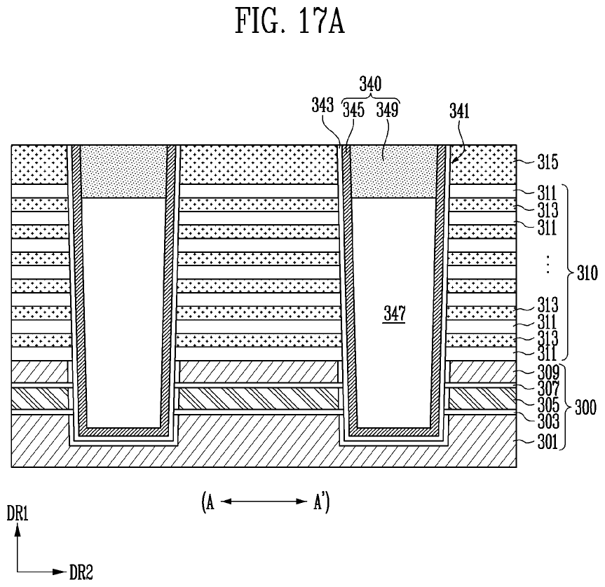

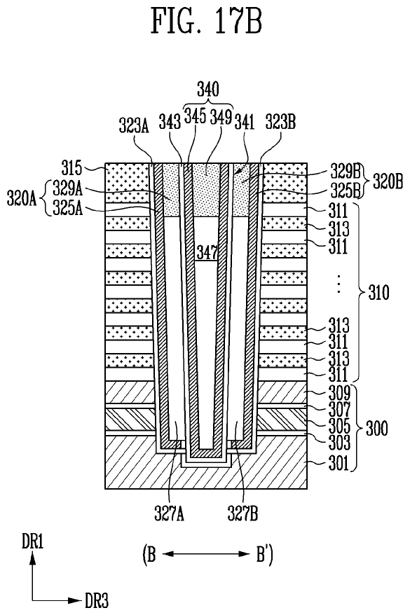

FIG. 16 is a plan view illustrating a process of forming first to third capping doped semiconductor layers. FIG. 17A is a sectional view taken along line A-A′ shown in FIG. 16, and FIG. 17 is a sectional view taken along line B-B′ shown in FIG. 16.

Referring to FIGS. 16, 17A, and 17B, a recess region may be formed by removing an upper portion of each of the first to third core insulating layers 327A, 327B, and 347. Subsequently, first to third capping doped semiconductor layers 329A, 329B, and 349 may be formed by filling the recess region with a doped semiconductor layer.

According to the above-described process, a first channel structure 320A may be formed, which includes the first channel layer 325A and the first capping doped semiconductor layer 329A in contact therewith. In addition, a second channel structure 320B may be formed, which includes the second channel layer 325B and the second capping doped semiconductor layer 329B in contact therewith. In addition, a third channel structure 340 may be formed, which includes the third channel layer 345 and the third capping doped semiconductor layer 349 in contact therewith.

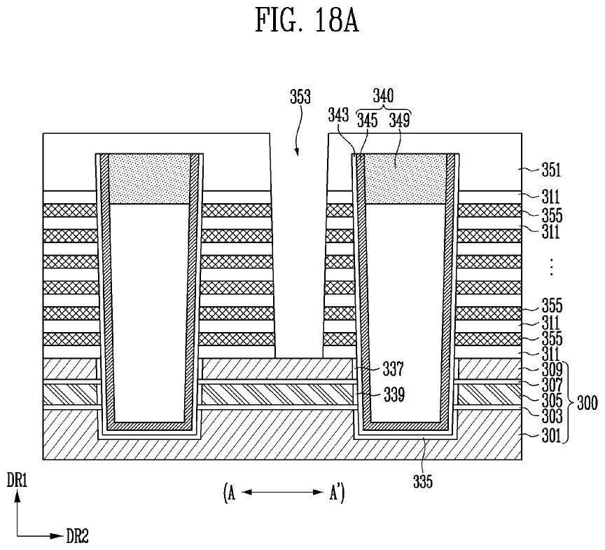

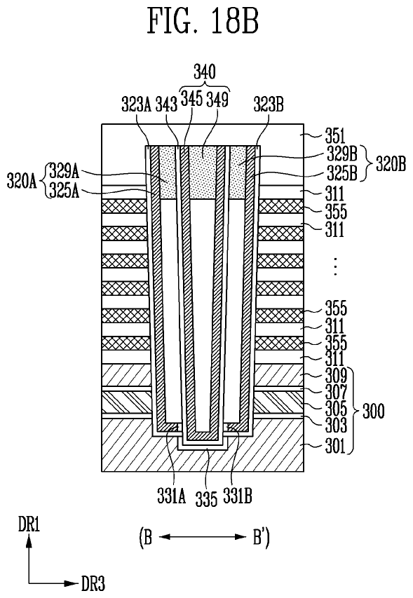

FIGS. 18A and 18B are sectional views illustrating a process of forming a gate stack structure.

Referring to FIGS. 18A and 18B, the mask layer 315 shown in FIGS. 17A and 17B may be removed. Subsequently, a first insulating layer 351 may be formed on the stack structure 310 shown in FIGS. 17A and 17B to cover the first to third channel structures 320A, 320B, and 340.

Subsequently, a slit 353 may be formed, which penetrates the first insulating layer 351 and the stack structure shown in FIGS. 17A and 17B. The plurality of first material layers 311 and the plurality of second material layers 313, which are shown in FIGS. 17A and 17B, may be etched to form the slit 353. During the etching process for forming the slit 353, the etch stop layer 309 may be used to detect an etching end time. In the case of an embodiment in which the first material layer 311 shown in FIGS. 17A and 17B is provided as an interlayer insulating layer and the second material layer 313 is formed of a sacrificial material, the plurality of second material layers 313 may be replaced with a plurality of conductive layers 355 through the slit 353. Accordingly, a gate stack structure may be formed, which includes a plurality of interlayer insulating layers (e.g., 311) and the plurality of conductive layers 355 and is partitioned by the slit 353.

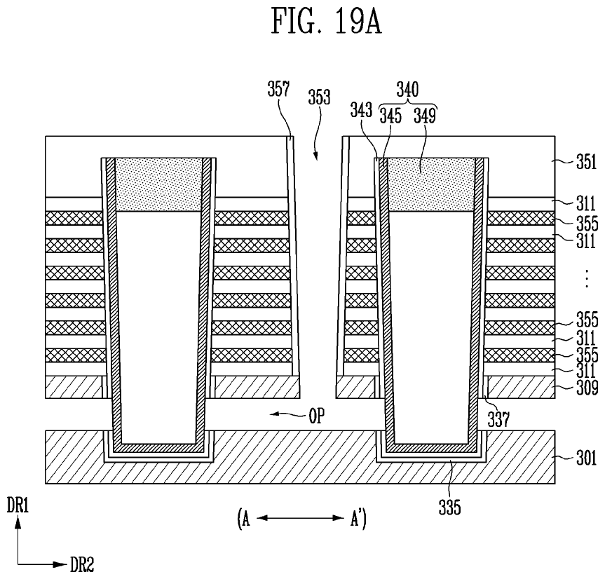

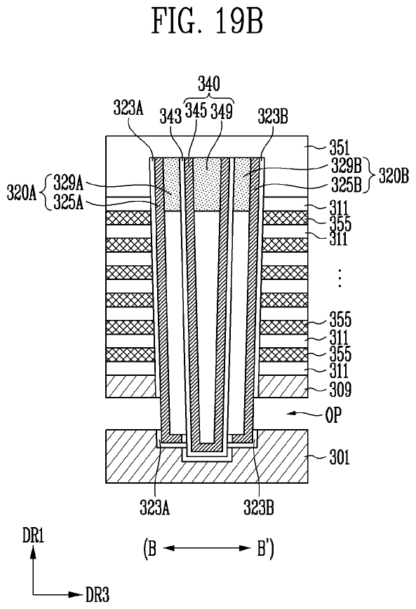

FIGS. 19A and 19B are sectional views illustrating a process of exposing a sidewall of the first to third channel layers.

Referring to FIGS. 19A and 19B, a sidewall insulating layer 357 may be formed on a sidewall of the slit 353. Subsequently, the sacrificial layer 305 shown in FIGS. 18A and 18B may be selectively removed. Accordingly, the first protective layer 303, the second protective layer 307, the first memory layer 323A, the second memory layer 323B, and the third lower interposition insulating layer 339, which are shown in FIGS. 18A and 18B, may be exposed. Subsequently, a portion of the first memory layer 323A, the second memory layer 323B, and the third memory layer 343, which are shown in FIGS. 18A and 18B, may be exposed such that a sidewall of the first to third channel layers 325A, 325B, and 345 is exposed. The first protective layer 303, the second protective layer 307, and the third lower interposition insulating layer 339, which are shown in FIGS. 18A and 18B, may be removed.

As described above, the sacrificial layer 305, the first protective layer 303, the second protective layer 307, and the third lower interposition insulating layer 339, which are shown in FIGS. 18A and 18B, are removed, and a portion of each of the first memory layer 323A, the second memory layer 323B, and the third memory layer 343 is removed, thereby forming an opening OP between the etch stop layer 309 and the lower doped semiconductor layer 301. The sidewall of each of the first to third channel layers 325A, 325B, and 345 may be exposed through the opening OP.

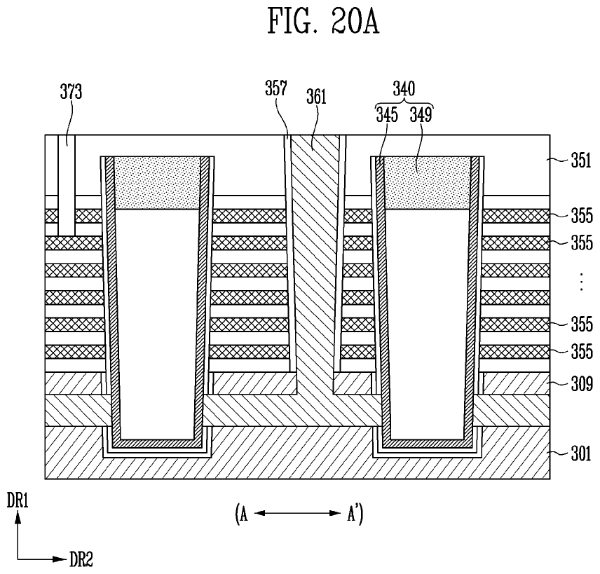

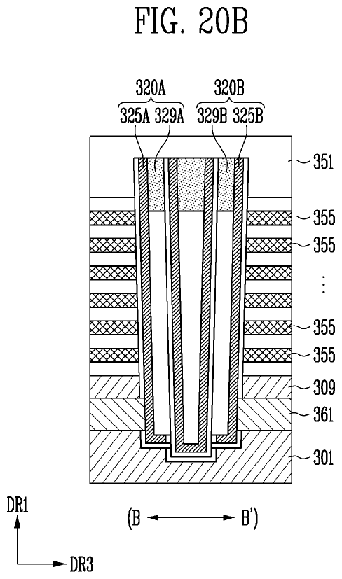

FIGS. 20A and 20B are sectional views illustrating a process of forming a doped semiconductor layer.

Referring to FIGS. 20A and 20B, a doped semiconductor layer 361 may be formed inside the slit 353 and the opening OP, which are shown in FIGS. 19A and 19B. The doped semiconductor layer 361 may be in contact with the sidewall of each of the first to third channel layers 325A, 325B, and 345 through the opening OP shown in FIGS. 19A and 19B.

A line isolation structure 373 may be formed to penetrate at least one conductive layer 355 adjacent to the first insulating layer 351 among the plurality of conductive layers 355 and the first insulating layer 351.

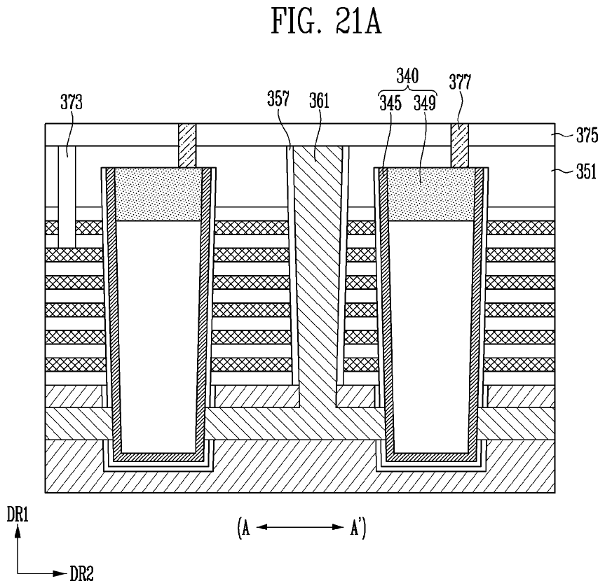

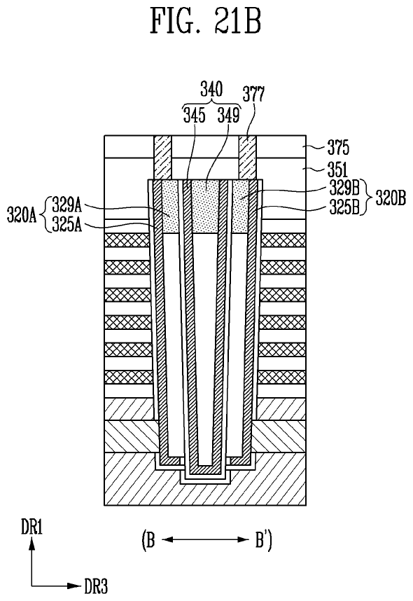

FIGS. 21A and 21B are sectional views illustrating a process of forming a plurality of bit line contacts.

Referring to FIGS. 21A and 21B, a second insulating layer 375 may be formed on the first insulating layer 351. Subsequently, a plurality of bit line contacts 377 may be formed, which penetrate the first insulating layer 351 and the second insulating layer 375. The plurality of bit line contacts 377 may be formed of various conductive materials. Each bit line contact 377 may extend in the first direction DR1 from a channel structure corresponding thereto among the first to third channel structures 320A, 320B, and 340.

Subsequently, a subsequent process for forming a plurality of bit lines may be performed.

The semiconductor memory device described with reference to FIGS. 4A to 4C and 5A to 5C may be manufactured by using the processes described with reference to FIGS. 8 to 21B.

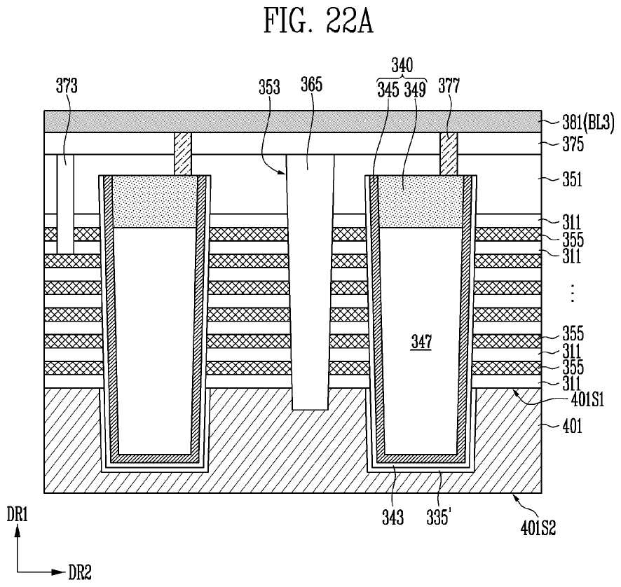

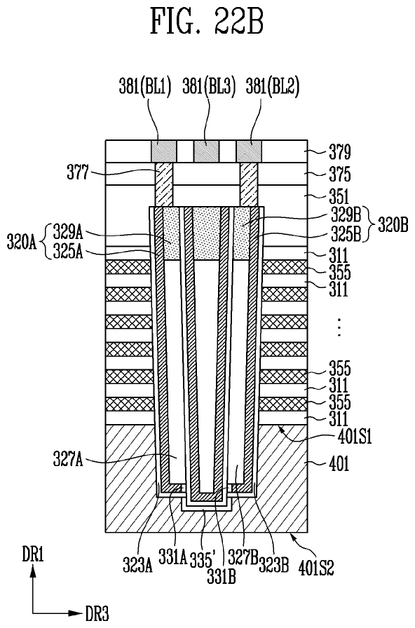

FIGS. 22A, 22B, 23A, 23B, 24A, 24B, 25A, 25B, 26A, and 26B are process sectional views illustrating a manufacturing method of a semiconductor memory device in accordance with an embodiment of the present disclosure. FIGS. 22A, 23A, 24A, 25A, and 26A are process sectional views taken along a direction in which a bit line extends, and FIGS. 22B, 23B, 24B, 25B, and 26B are process sectional views taken along a direction intersecting the bit line.

FIGS. 22A and 22B are sectional views illustrating a process of a memory cell array, a bit line contact, and a bit line.

Referring to FIGS. 22A and 22B, the memory cell array may include a first memory layer 323A, a second memory layer 323B, a third memory layer 343, a first interposition insulating layer 331A, a second interposition insulating layer 331B, a lower interposition insulating layer 335′, a first channel layer 325A and a first capping doped semiconductor layer 329A of a first channel structure 320A, a second channel layer 325B and a second capping doped semiconductor layer 329B of a second channel structure 320B, a third channel layer 345 and a third capping doped semiconductor layer 349 of a third channel structure 340, a first core insulating layer 327A, a second core insulating layer 327B, a third core insulating layer 347, a first insulating layer 351, a plurality of conductive layers 355, and a line isolation structure 373, which are formed by using the processes described with reference to FIGS. 8 to 18B. A plurality of conductive layers 355 along with a plurality of first material layers 311 may be alternately stacked in the first direction DR1, to form a gate stack structure. The first material layer 311 may be provided as an interlayer insulating layer.

The above-described memory cell array may be formed on a first semiconductor substrate 401. The first semiconductor substrate 401 may include a first surface 410S1 facing in the first direction DR1 and a second surface 401S2 facing in a direction opposite to the first surface 401S1. The process of forming the memory cell array may be performed on the first surface 401S1 of the first semiconductor substrate 401.

The first memory layer 323A, the second memory layer 323B, the third memory layer 343, the first channel structure 320A, the second channel structure 320B, the third channel structure 340, the first core insulating layer 327A, the second core insulating layer 327B, and the third core insulating layer 347 may extend to the inside of the first semiconductor substrate 401. The lower interposition insulating layer 335′ may be formed by oxidizing a portion of the first semiconductor substrate 401, and be disposed between the first semiconductor substrate 401 and the third memory layer 343.

The plurality of first material layers 311 and the plurality of conductive layers 355 may be partitioned as the gate stack structure by a slit 353. After the gate stack structure is formed, the slit 353 may be filled with a slit insulating layer 365.

Subsequently, a second insulating layer 375 and a plurality of bit line contacts 377 may be formed by using the processes described with reference to FIGS. 21A and 21B. Subsequently, a process of forming a third insulating layer 379 on the second insulating layer 375 and a process of forming a plurality of bit lines 381 penetrating the third insulating layer 379 may be performed. The plurality of bit lines 381 may be formed of various conductive materials. The plurality of bit lines 381 may include a first bit line BL1 connected to the first channel structure 320A, a second bit line connected to the second channel structure 320A, and a third bit line BL3 connected to the third channel structure 340. The arrangement order of the first bit line BL1, the second bit line BL2, and the third bit line BL3 may be changed according to an arrangement of the first channel structure 320A, the second channel structure 320B, and the third channel structure 340. In an embodiment, the first to third channel structures 320A, 320B, and 340 may be arranged in the same direction as the first to third memory cell strings CS1, CS2, and CS3 shown in FIG. 4A. In this embodiment, the third bit line BL3 may be disposed between the first bit line BL1 and the second bit line BL2.

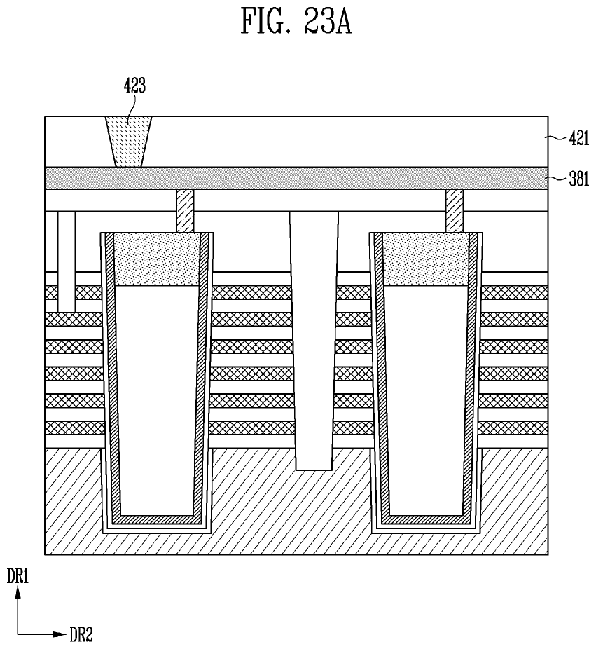

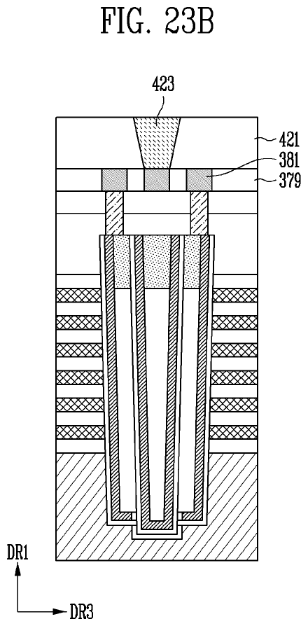

FIGS. 23A and 23B are sectional views illustrating a process of forming a memory cell array-side bonding structure.

Referring to FIGS. 23A and 23B, the process of forming the memory cell array-side bonding structure may include a process of forming a first bonding insulating layer 421 on the third insulating layer 379 and a process of forming a plurality of first conductive bonding pads 423 penetrating the first bonding insulating layer 421. Some of the plurality of first conductive bonding pads 423 may be connected to the memory cell array. In an embodiment, the plurality of first conductive bonding pas 423 may include a bonding pad connected to the bit line 381.

The first bonding insulating layer 421 may include silicon oxide, silicon oxynitride, silicon carbonitride, and the like. The first conductive bonding pad may include a metal including copper, a copper alloy, and the like.

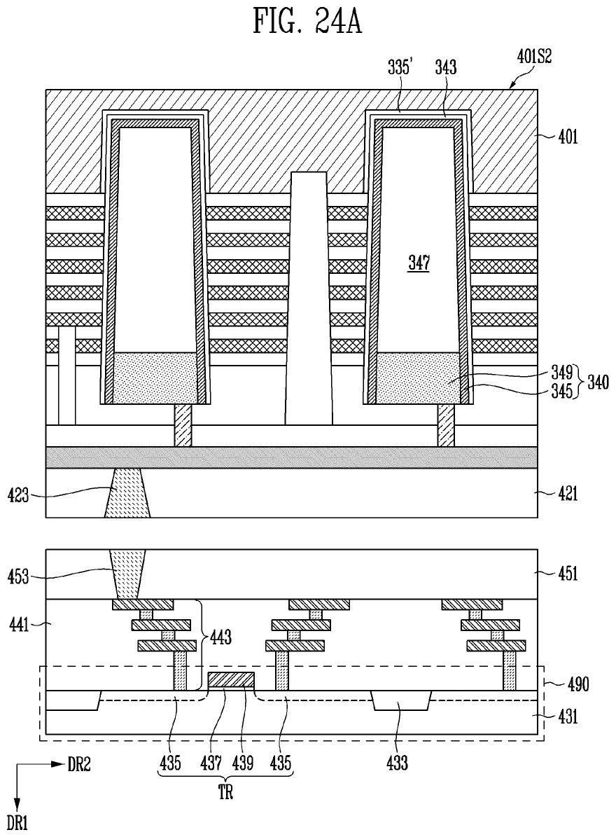

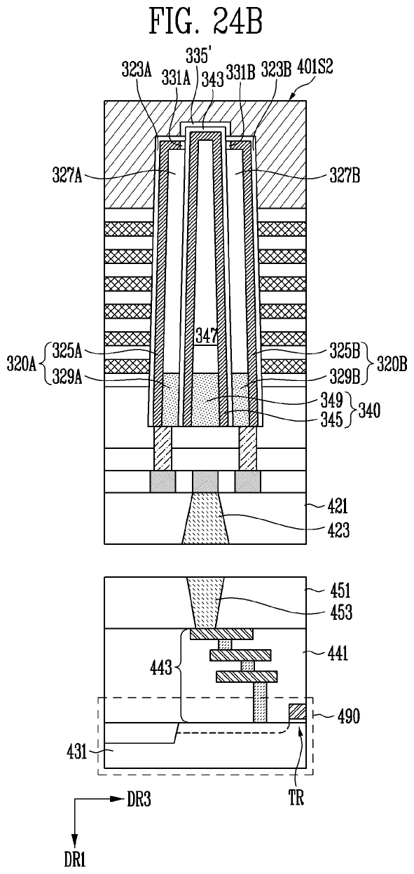

FIGS. 24A and 24B are sectional views illustrating a bonding process.

Referring to FIGS. 24A and 24B, a structure including a peripheral circuit structure 490 may be provided through a separate process. The peripheral circuit structure 490 may include a plurality of transistors TR.

Each transistor TR may be disposed in an active region of a second semiconductor substrate 431. The second semiconductor substrate 431 may be a silicon substrate, a silicon-germanium substrate, a germanium substrate, a single crystalline substrate, or a substrate including a single crystalline epitaxial layer. The active region of the second semiconductor substrate 431 may be partitioned by an isolation layer 433.

Each transistor TR may include a gate insulating layer 437, a gate electrode 439, and junctions 435. The gate insulating layer 437 and the gate electrode 439 may be stacked on the active region of the second semiconductor substrate 431. The junctions 435 may be formed inside the active region of the second semiconductor substrate 431 at both sides of the gate electrode 439, and be defined as regions into which at least one of an n-type impurity and a p-type impurity is implanted. The junctions 435 may be provided as a source region and a drain region of a transistor TR corresponding thereto.

The peripheral circuit structure 490 may be covered by a lower insulating structure 441. The lower insulating structure 441 may include two or more insulating layers stacked on the second semiconductor substrate 431.

The plurality of transistors TR may be connected to a plurality of interconnections 443. Each interconnection 443 may include two or more sub-conductive layers. The plurality of interconnections 443 may be disposed inside the lower insulating structure 441.

A second bonding insulating layer 451 may be disposed on the lower insulating structure 441. The second bonding insulating layer 451 may be penetrated by a plurality of second conductive bonding pads 453. The plurality of second conductive bonding pads 453 may include a bonding pad connected to the transistor TR. The second bonding insulating layer 451 may include silicon oxide, silicon oxynitride, silicon carbonitride, and the like. The second conductive bonding pad 453 may include a metal including copper, a copper alloy, and the like.

The plurality of first conductive bonding pads 423 provided through the process described above with reference to FIGS. 23A and 23B may be aligned to face the plurality of second conductive bonding pads 453. Subsequently, each first conductive bonding pad 423 may be bonded to a second conductive bonding pad 453 corresponding thereto, and the first bonding insulating layer 421 may be bonded to the second bonding insulating layer 451.

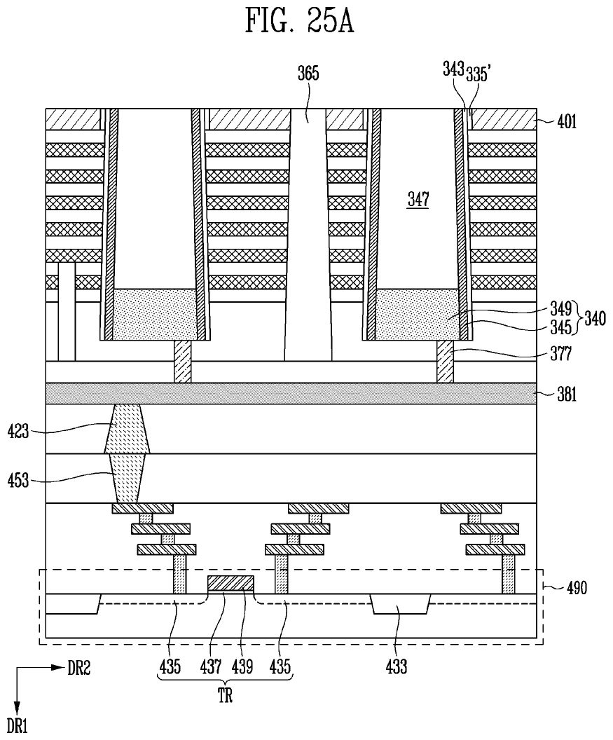

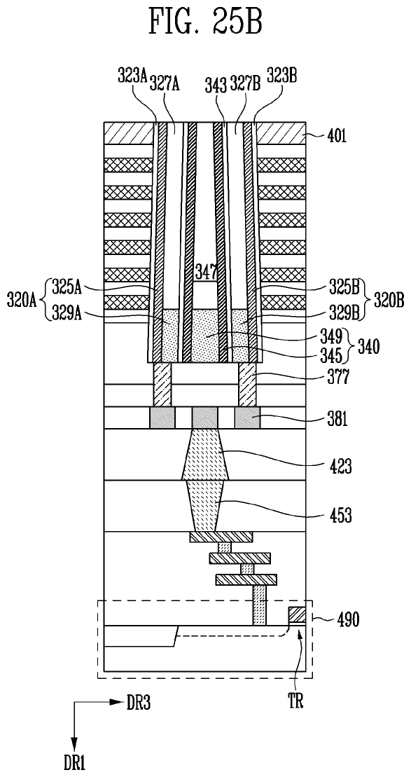

FIGS. 25A and 25B are sectional views illustrating a process of exposing the first channel structure, the second channel structure, and the third channel structure.

Referring to FIGS. 25A and 25B, the memory cell array may be electrically connected to the peripheral circuit structure 490 through the bonding process described with reference to FIGS. 24A and 24B. In an embodiment, each of the first channel structure 320A, the second channel structure 320B, and the third channel structure 340 of the memory cell array may be electrically connected to the transistor TR of the peripheral circuit structure 490 via a bit line 381, a first conductive bonding pad 423, and a second conductive bonding pad 453, which correspond thereto.

After the bonding process, at least a portion of the first semiconductor substrate 401 may be removed such that the first channel layer 325A, the second channel layer 325B, and the third channel layer 345 are exposed. In an embodiment, the first semiconductor substrate 410, the first channel structure 320A, the second channel structure 320B, and the third channel structure 340 may be planarized from the second surface 401S2 of the first semiconductor substrate 401 shown in FIGS. 24A and 24B by using a chemical mechanical polishing (CMP) process, or the like. Accordingly, portions of the lower interposition insulating layer 335, the first memory layer 323A, the second memory layer 323B, and the third memory layer 343 may be removed, and the first channel layer 325A, the second channel layer 325B, and the third channel layer 345 may be exposed. A portion of the first semiconductor substrate 401 may remain to surround sidewalls of the first channel structure 320A, the second channel structure 320B, and the third channel structure 340. However, the embodiment of the present disclosure is not limited thereto. In an embodiment, the first semiconductor substrate 401 may be completely removed.

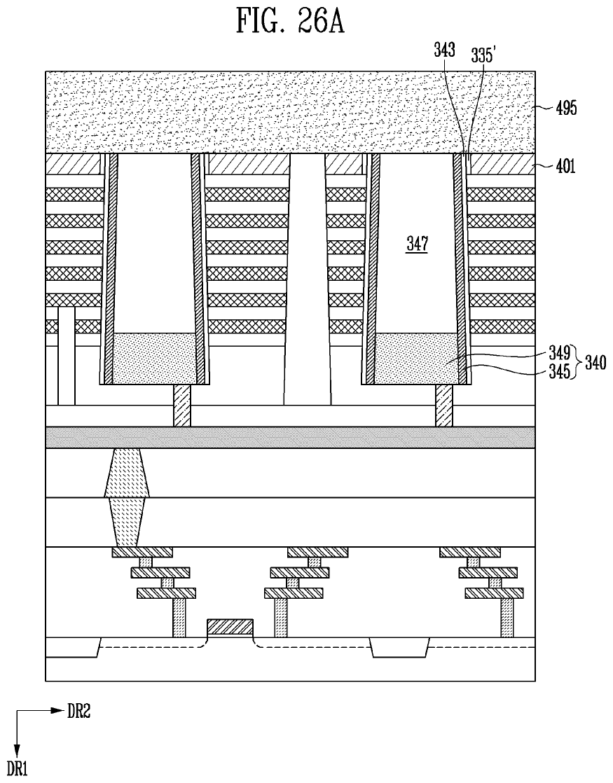

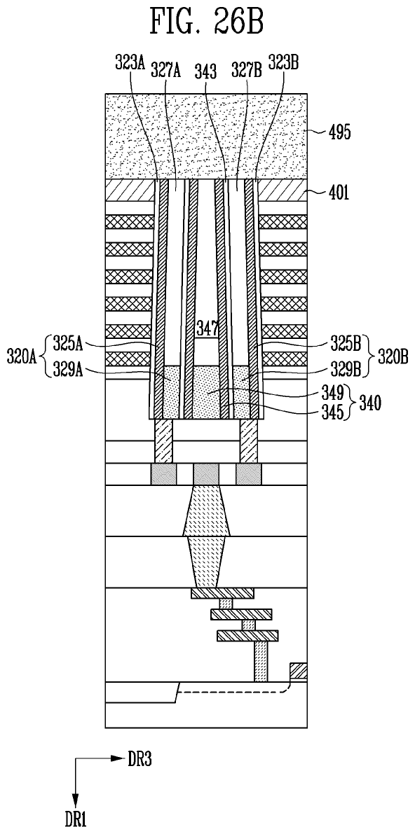

FIGS. 26A and 26B are sectional views illustrating a process of a doped semiconductor layer.

Referring to FIGS. 26A and 26B, a doped semiconductor layer 495 may be formed on end portions of the first channel layer 325A, the second channel layer 325B, and the third channel layer 345 through the process described with reference to FIGS. 25A and 25B. The doped semiconductor layer 495 may include at least one of an n-type impurity and a p-type impurity. The impurity inside the doped semiconductor layer 495 may be diffused into the end portions of the first channel layer 325A, the second channel layer 325B, and the third channel layer 345 and the first semiconductor substrate 401.

The semiconductor memory device described with reference to FIGS. 6A and 6B may be formed by using the processes described with reference to FIGS. 22A to 26B.

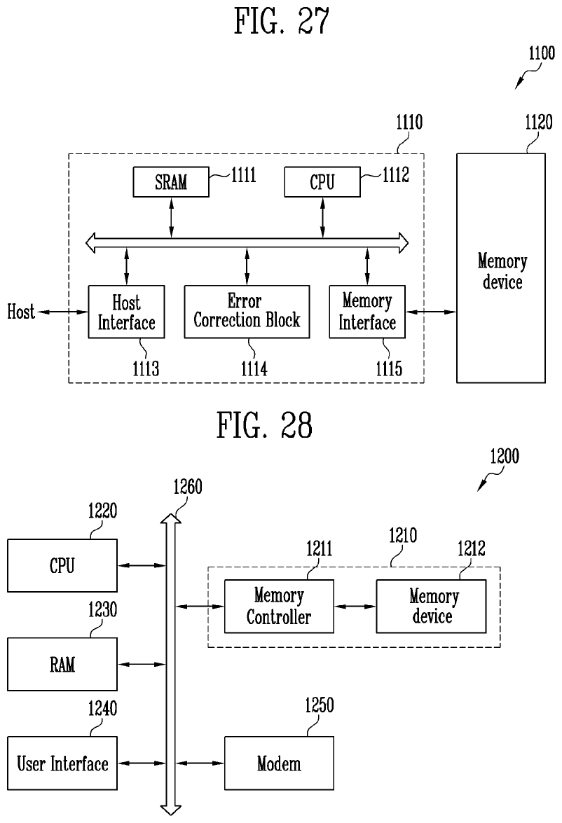

FIG. 27 is a block diagram illustrating a configuration of a memory system in accordance with an embodiment of the present disclosure.

Referring to FIG. 27, the memory system 1100 includes a memory device 1120 and a memory controller 1110.

The memory device 1120 may be a multi-chip package configured with a plurality of flash memory chips. The memory device 1120 may include a first channel structure, a second channel structure, a third channel structure, and a gate stack structure surrounding the first to third channel structures without being interposed between the first to third channel structures.

The memory controller 1110 controls the memory device 1120, and may include a Static Random Access Memory (SRAM) 1111, a Central Processing Unit (CPU) 1112, a host interface 1113, an error correction block 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The error correction block 1114 detects an error included in a data read from the memory device 1120, and corrects the detected error. The memory interface 1115 interfaces with the memory device 1120. The memory controller 1110 may further include a Read Only Memory (ROM) for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

FIG. 28 is a block diagram illustrating a configuration of a computing system in accordance with an embodiment of the present disclosure.

Referring to FIG. 28, the computing system 1200 may include a CPU 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, a mobile DRAM, and the like may be further included.

The memory system 1210 may be configured with a memory device 1212 and a memory controller 1211. The memory device 1212 may be configured the same as the memory device 1120 described above with reference to FIG. 27. The memory controller 1211 may be configured the same as the memory controller 1110 described above with reference to FIG. 27.

In accordance with the present disclosure, in an embodiment, a channel layer inside a first channel hole may be isolated into a first channel structure and a second channel structure through a second channel hole intersecting the first channel hole, and the second channel hole may be used as a space for a third channel structure. Accordingly, in an embodiment, the arrangement density of channel structure within a limited region may be increased, so that the degree of integration of memory cells may be improved.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described examples of embodiments but should be determined by not only the appended claims but also the equivalents thereof.

What is claimed is:

1. A semiconductor memory device comprising:
a first channel structure extending in a first direction;
a second channel structure extending in the first direction;
a third channel structure extending in the first direction, wherein the third channel structure is disposed between the first channel structure and the second channel structure; and
a plurality of conductive layers surrounding the first channel structure, the second channel structure, and the third channel structure,
wherein the plurality of conductive layers are stacked in the first direction and are spaced apart from each other in the first direction, and
wherein the third channel structure is spaced apart from the first channel structure without interposition of the plurality of conductive layers between the third channel structure and the first channel structure, and
wherein the third channel structure is spaced apart from the second channel structure without interposition of the plurality of conductive layers between the third channel structure and the second channel structure.

2. The semiconductor memory device of claim 1, wherein the third channel structure further protrudes laterally than the first channel structure and the second channel structure.

3. The semiconductor memory device of claim 1, further comprising:
a first memory layer located between each of the plurality of conductive layers and the first channel structure;
a second memory layer located between each of the plurality of conductive layers and the second channel structure; and
a third memory layer disposed between each of the plurality of conductive layers and the third channel structure, the third memory layer surrounding an outer sidewall of the third channel structure.

4. The semiconductor memory device of claim 3, wherein each of the first memory layer and the second memory layer forms a common plane with the third memory layer.

5. The semiconductor memory device of claim 3, further comprising:
a first interposition insulating layer located between the third memory layer and the first channel structure; and
a second interposition insulating layer located between the third memory layer and the second channel structure.

6. The semiconductor memory device of claim 1, further comprising a doped semiconductor structure connected to the first channel structure, wherein the doped semiconductor structure is connected to the second channel structure, and wherein the doped semiconductor structure is connected to the third channel structure,
wherein the doped semiconductor structure includes:
a lower doped semiconductor layer overlapping with the plurality of conductive layers; and
a channel contact structure disposed between the plurality of conductive layers and the lower doped semiconductor layer, wherein the channel contact structure is in contact with a sidewall of the first channel structure, wherein the channel contact structure is in contact with a sidewall of the second channel structure, and the channel contact structure is in contact with a sidewall of the third channel structure.

7. The semiconductor memory device of claim 6,
wherein the third channel structure further protrudes to the inside of the lower doped semiconductor layer than the first channel structure, and
wherein the third channel structure further protrudes to the inside of the lower doped semiconductor layer than the second channel structure.

8. The semiconductor memory device of claim 6, further comprising a first lower interposition insulating layer interposed between the third channel structure and the lower doped semiconductor layer.

9. The semiconductor memory device of claim 1, further comprising a doped semiconductor structure connected to the first channel structure, wherein the doped semiconductor structure connected to the second channel structure, and wherein the doped semiconductor structure connected to the third channel structure,
wherein the doped semiconductor structure is in contact with an end of the first channel structure,
wherein the doped semiconductor structure is in contact with an end of the second channel structure, and
wherein the doped semiconductor structure is in contact with an end of the third channel structure.

10. The semiconductor memory device of claim 1, further comprising:
a first bit line connected to the first channel structure;
a second bit line connected to the second channel structure; and
a third bit line connected to the third channel structure,
wherein the first, second, and third bit lines extend substantially in parallel to one another.

11. The semiconductor memory device of claim 10, wherein the third bit line is disposed between the first bit line and the second bit line,
wherein the first channel structure and the second channel structure are spaced apart from each other in a direction intersecting the first to third bit lines, and
wherein the third channel structure protrudes further than the first channel structure in an extending direction of the first, second, and third bit lines, and
wherein the third channel structure protrudes further than the second channel structure in the extending direction of the first, second, and third bit lines.

12. The semiconductor memory device of claim 10, wherein the first bit line is disposed between the second bit line and the third bit line,
wherein the first channel structure and the second channel structure are spaced apart from each other in an extending direction of the first, second, and third bit lines, and
wherein the third channel structure protrudes further than the first channel structure in a direction intersecting the first, second, and third bit lines, and
wherein the third channel structure protrudes further than the second channel structure in the direction intersecting the first, second, and third bit lines.

13. The semiconductor memory device of claim 12, wherein the first, second, and third bit lines overlap with the third channel structure.

14. A semiconductor memory device comprising:
a plurality of bit lines;
a doped semiconductor structure overlapping with the plurality of bit lines;
a gate stack structure including a plurality of conductive layers disposed to be spaced apart from each other in a first direction in which the doped semiconductor structure faces the plurality of bit lines, the gate stack structure including a first channel hole and a second channel hole, wherein the first channel hole and the second channel hole penetrate the plurality of conductive layers, and wherein the first channel hole and the second channel hole intersect each other;
a first channel structure disposed inside the first channel hole;
a second channel structure disposed inside the first channel hole, wherein the second channel hole isolates the first channel structure from the second channel structure;
a first memory layer extending along a sidewall of the first channel hole;
a second memory layer extending along a sidewall of the first channel hole, wherein the second channel hole isolates the first memory layer from the second memory layer;
a third channel structure disposed in an overlapping region in which the first channel hole and the second channel hole overlap with each other; and
a third memory layer extending along a sidewall of the third channel structure.

15. The semiconductor memory device of claim 14,
wherein the second channel hole includes both sidewalls further protruding laterally than the first channel hole,
wherein the third channel structure extends along both the sidewalls of the second channel hole, and
wherein the third memory layer extends along both the sidewalls of the second channel hole.

16. The semiconductor memory device of claim 14, wherein the doped semiconductor structure includes:
a lower doped semiconductor layer overlapping with the gate stack structure; and
a channel contact structure disposed between the gate stack structure and the lower doped semiconductor layer, and
wherein the channel contact structure protrudes toward the first channel structure, the second channel structure, and the third channel structure to penetrate the first memory layer, the second memory layer, and the third memory layer.

17. The semiconductor memory device of claim 14, wherein the doped semiconductor structure is in contact with an end of the first channel structure,
wherein the doped semiconductor structure is in contact with an end of the second channel structure, and
wherein the doped semiconductor structure is in contact with an end of the third channel structure.

18. The semiconductor memory device of claim 14, wherein the plurality of bit lines include:
a first bit line connected to the first channel structure;
a second bit line connected to the second channel structure; and
a third bit line connected to the third channel structure.

19. The semiconductor memory device of claim 14, wherein one of the first channel hole and the second channel hole is formed in an elliptical shape having a major axis along an extending direction of the plurality of bit lines, and
wherein the other of the first channel hole and the second channel hole is formed in an elliptical shape having a major axis along a direction intersecting the plurality of bit lines.

20. A method of manufacturing a semiconductor memory device, the method comprising:
forming a first channel hole penetrating a stack structure;
forming a preliminary memory layer along a surface of the first channel hole;
forming a preliminary channel layer on the preliminary memory layer;
forming a second channel hole intersecting the first channel hole, the second channel hole penetrating the preliminary memory layer and the preliminary channel layer;
forming a memory layer inside the second channel hole; and
forming a channel layer disposed inside the second channel hole, the channel layer extending along a surface of the memory layer.

21. The method of claim 20, wherein the preliminary memory layer is isolated into a first memory layer and a second memory layer by the second channel hole.

22. The method of claim 20, wherein the preliminary channel layer is isolated into a first channel layer and a second channel layer by the second channel hole.

23. The method of claim 20, comprising:
before the second channel hole is formed,
filling a central region of the first channel hole, which is opened by the preliminary channel layer, with a preliminary core insulting layer,
wherein the preliminary core insulating layer is isolated into a first core insulating layer and a second core insulating layer by the second channel hole.

24. The method of claim 23, further comprising:
oxidizing a portion of the preliminary channel layer through the second channel hole;
filling a central region of the second channel hole, which is opened by the channel layer, with a third core insulating layer; and
replacing an upper portion of the first core insulating layer, an upper portion of the second core insulating layer and an upper portion of the third core insulating layer with capping doped semiconductor layers, respectively.
